(19) United States
(12) Patent Application Publication
(10) Pub. No.: US 2025/0311604 A1
(43) Pub. Date: Oct. 2, 2025

(54) DISPLAY DEVICE AND ELECTRONIC DEVICE INCLUDING THE SAME

(71) Applicant: Samsung Display Co., LTD., Yongin-si (KR)

(72) Inventors: Gina YOO, Yongin-si (KR); Hyomin KIM, Yongin-si (KR); Bumkyun CHOI, Yongin-si (KR)

(21) Appl. No.: 19/024,408

(22) Filed: Jan. 16, 2025

(30) Foreign Application Priority Data
Mar. 29, 2024 (KR) 10-2024-0043621

(51) Int. Cl. H10K 59/80; H10K 59/38; H10K 59/40

(52) U.S. Cl. CPC H10K 59/8792; H10K 59/38; H10K 59/40

(57) ABSTRACT

A display device includes: a first display element in a first display area; a second display element in a second display area and configured to emit light of the same wavelength as the first display element; a first touch conductive pattern; a touch insulating layer covering the first touch conductive pattern, including protrusions, and providing a recess defined by the protrusions, the protrusions overlapping a first emission area of the first display element and a second emission area of the second display element, respectively; and a first light-blocking layer on the recess of the touch insulating layer and defining a first opening and a second opening, the first opening overlapping the first emission area, and the second opening overlapping the second emission area. An area of the first opening of the first light-blocking layer is less than an area of the second opening of the first light-blocking layer.

This application claims priority to Korean Patent Application No. 10-2024-0043621, filed on Mar. 29, 2024, and all the benefits accruing therefrom under 35 U.S.C. § 119, the content of which in its entirety is herein incorporated by reference.

### BACKGROUND

### 1. Field

One or more embodiments relate to a device, and more particularly, to a display device and an electronic device including the display device.

### 2. Description of the Related Art

Mobility-based electronic devices have been widely used. As mobile electronic devices, tablet personal computers (PCs) have been widely used in recent years, in addition to small electronic devices such as mobile phones.

Such mobile electronic devices includes a display device for providing visual information such as an image or video to a user, in order to support various functions. Recently, as other components for driving a display device have been miniaturized, the proportion occupied by a display device in an electronic device has gradually increased, and a structure that is bendable from a flat state to have a certain angle has been developed.

### SUMMARY

One or more embodiments include a display device in which side visibility is reduced to reduce risks of personal information exposure in public and multi-purpose facilities. One or more embodiments include a display device having improved display quality. However, the above aspects are examples, and the scope of the disclosure is not limited thereto.

Additional aspects will be set forth in part in the description which follows and, in part, will be apparent from the description, or may be learned by practice of the presented embodiments of the disclosure.

According to one or more embodiments, a display device includes: a substrate including a first display area and a second display area adjacent to the first display area, a first display element disposed in the first display area, a second display element disposed in the second display area and configured to emit light of a same wavelength as the first display element, a first touch conductive pattern disposed on the first display element and the second display element, a touch insulating layer covering the first touch conductive pattern, including protrusions, and providing a recess defined by the protrusions, the protrusions overlapping a first emission area of the first display element and a second emission area of the second display element, respectively, in a plan view, a first light-blocking layer disposed on the recess of the touch insulating layer and defining a first opening and a second opening therein, the first opening overlapping the first emission area of the first display element, and the second opening overlapping the second emission area of the second display element in the plan view, and a color filter layer disposed on the touch insulating layer and the first light-blocking layer and including a first color filter and a second color filter, the first color filter overlapping the first emission area of the first display element, and the second color filter overlapping the second emission area of the second display element in the plan view, where an area of the first opening of the first light-blocking layer is less than an area of the second opening of the first light-blocking layer in the plan view.

In an embodiment, a thickness of the first color filter may be substantially the same as a thickness of a corresponding portion of the second color filter.

In an embodiment, a portion of the first color filter may be disposed between the first light-blocking layer and a protrusion overlapping the first emission area, from among the protrusions of the touch insulating layer, and a portion of the second color filter may be disposed between the first light-blocking layer and a protrusion overlapping the second emission area, from among the protrusions of the touch insulating layer in the plan view.

In an embodiment, in the plan view, a minimum distance between the first light-blocking layer and a protrusion overlapping the first emission area, from among the protrusions of the touch insulating layer, may be substantially the same as a minimum distance between the first light-blocking layer and a protrusion overlapping the second emission area, from among the protrusions of the touch insulating layer.

In an embodiment, the protrusions of the touch insulating layer may not overlap the first light-blocking layer in the plan view.

In an embodiment, the display device may further include a second touch conductive pattern disposed on the recess of the touch insulating layer, wherein the first light-blocking layer may cover the second touch conductive pattern.

In an embodiment, the first touch conductive pattern and the second touch conductive pattern may not overlap the first emission area and the second emission area in the plan view.

In an embodiment, the display device may further include a second light-blocking layer disposed on the color filter layer and disposed in the first display area, wherein the second light-blocking layer may define an opening overlapping the first opening of the first light-blocking layer in the plan view.

In an embodiment, the display device may further include a pixel-defining layer disposed on the substrate and defining a first pixel opening and a second pixel opening therein, the first pixel opening defining the first emission area, and the second pixel opening defining the second emission area, where the first pixel opening may overlap the first opening of the first light-blocking layer, and the second pixel opening may overlap the second opening of the first light-blocking layer in the plan view.

In an embodiment, in the plan view, a minimum distance between the first pixel opening and the first light-blocking layer may be less than a minimum distance between the second pixel opening and the second opening of the first light-blocking layer.

In an embodiment, the touch insulating layer may include a first layer and a second layer, the first layer having a flat upper surface, and the second layer being disposed on the first layer and arranged in the first opening and the second opening of the first light-blocking layer in the plan view, and the second layer of the touch insulating layer may define the protrusions.

According to one or more embodiments, a display device includes a substrate including a first display area and a second display area adjacent to the first display area, a first display element disposed in the first display area, a second display element disposed in the second display area and configured to emit light of a same wavelength as the first display element, a touch conductive pattern disposed on the first display element and the second display element, a touch insulating layer covering the touch conductive pattern and including a first protrusion and a second protrusion, the first protrusion overlapping a first emission area of the first display element, and the second protrusion overlapping a second emission area of the second display element in a plan view, a first light-blocking layer disposed on the touch insulating layer and defining a first opening and a second opening therein, the first opening overlapping the first emission area of the first display element and having a greater area than the first protrusion, and the second opening overlapping the second emission area of the second display element and having a greater area than the second protrusion in the plan view, and a color filter layer disposed on the touch insulating layer and the first light-blocking layer and including a first color filter and a second color filter, the first color filter overlapping the first emission area of the first display element, and the second color filter overlapping the second emission area of the second display element in the plan view, where an area of the first opening of the first light-blocking layer is less than an area of the second opening of the first light-blocking layer in the plan view.

In an embodiment, a thickness of the first color filter may be substantially the same as a thickness of a corresponding portion of the second color filter.

In an embodiment, a portion of the first color filter may be disposed between the first protrusion and the first light-blocking layer, and a portion of the second color filter may be disposed between the second protrusion and the first light-blocking layer.

In an embodiment, in the plan view, a minimum distance between the first protrusion of the touch insulating layer and the first light-blocking layer may be substantially the same as a minimum distance between the second protrusion of the touch insulating layer and the first light-blocking layer.

In an embodiment, the first protrusion and the second protrusion of the touch insulating layer may not overlap the first light-blocking layer in the plan view.

In an embodiment, the display device may further include a second touch conductive pattern disposed on the touch insulating layer, wherein the first light-blocking layer may cover the second touch conductive pattern.

In an embodiment, the display device may further include a second light-blocking layer disposed on the color filter layer and disposed in the first display area, wherein the second light-blocking layer may define an opening overlapping the first opening of the first light-blocking layer in the plan view.

In an embodiment, the display device may further include a pixel-defining layer disposed on the substrate and defining a first pixel opening and a second pixel opening therein, the first pixel opening defining the first emission area, and the second pixel opening defining the second emission area, where the first pixel opening may overlap the first opening of the first light-blocking layer in the plan view, and the second pixel opening may overlap the second opening of the first light-blocking layer in the plan view.

According to one or more embodiments, a display device includes a substrate including a first display area and a second display area adjacent to the first display area, a first display element group disposed in the first display area and including a plurality of light-emitting elements, a second display element group disposed in the second display area and including a plurality of light-emitting elements, an input sensing layer disposed on the first display element group and the second display element group, and a first light-blocking layer disposed on the input sensing layer and defining first openings and second openings therein, the first openings overlapping emission areas of the plurality of light-emitting elements of the first display element group, respectively, and the second openings overlapping emission areas of the plurality of light-emitting elements of the second display element group, respectively, in a plan view, where the input sensing layer includes a first touch conductive pattern, a touch insulating layer on the first touch conductive pattern, and a second touch conductive pattern on the touch insulating layer, the touch insulating layer includes protrusions and provides a recess defined by the protrusions, the protrusions overlapping the emission areas of the plurality of light-emitting elements of the first display element group and the emission areas of the plurality of light-emitting elements of the second display element group, respectively, in the plan view, the first light-blocking layer is disposed on the recess of the touch insulating layer, the first display element group includes a first-1 light-emitting element configured to emit light of a first wavelength, the second display element group includes a second-1 light-emitting element configured to emit light of a same wavelength as the first-1 light-emitting element, and an area of a first opening overlapping an emission area of the first-1 light-emitting element, from among the first openings of the first light-blocking layer, is less than an area of a second opening overlapping an emission area of the second-1 light-emitting element, from among the second openings of the first light-blocking layer in the plan view.

In an embodiment, the display device may further include a color filter layer disposed on the input sensing layer and including a first-1 color filter and a second-1 color filter, the first-1 color filter overlapping the emission area of the first-1 light-emitting element, and the second-1 color filter overlapping the emission area of the second-1 light-emitting element in the plan view, where a thickness of the first-1 color filter may be substantially the same as a thickness of a corresponding portion of the second-1 color filter.

In an embodiment, the first display element group may further include a first-2 light-emitting element adjacent to the first-1 light-emitting element and configured to emit light of a second wavelength, the second display element group may further include a second-2 light-emitting element adjacent to the second-1 light-emitting element and configured to emit light of a same wavelength as the first-2 light-emitting element, an area of a first opening overlapping an emission area of the first-2 light-emitting element, from among the first openings of the first light-blocking layer, may be less than an area of a second opening overlapping an emission area of the second-2 light-emitting element, from among the second openings of the first light-blocking layer in the plan view, the color filter layer may further include a first-2 color filter and a second-2 color filter, the first-2 color filter overlapping the emission area of the first-2 light-emitting element, and the second-2 color filter overlapping the emission area of the second-2 light-emitting element in the plan view, and a thickness of the first-2 color filter may be substantially the same as a thickness of a corresponding portion of the second-2 color filter.

In an embodiment, in the plan view, the first-1 color filter and the first-2 color filter may overlap each other in an area overlapping the first light-blocking layer, and the second-1 color filter and the second-2 color filter may overlap each other in an area overlapping the first light-blocking layer.

According to one or more embodiments, an electronic device includes a display device, wherein the display device may include a substrate comprising a first display area and a second display area adjacent to the first display area, a first display element disposed in the first display area, a second display element disposed in the second display area and configured to emit light of a same wavelength as the first display element, a first touch conductive pattern disposed on the first display element and the second display element, a touch insulating layer covering the first touch conductive pattern, comprising protrusions, and providing a recess defined by the protrusions, the protrusions overlapping a first emission area of the first display element and a second emission area of the second display element, respectively, in a plan view, a first light-blocking layer disposed on the recess of the touch insulating layer and defining a first opening and a second opening therein, the first opening overlapping the first emission area of the first display element, and the second opening overlapping the second emission area of the second display element in the plan view, and a color filter layer disposed on the touch insulating layer and the first light-blocking layer and comprising a first color filter and a second color filter, the first color filter overlapping the first emission area of the first display element, and the second color filter overlapping the second emission area of the second display element in the plan view, wherein an area of the first opening of the first light-blocking layer is less than an area of the second opening of the first light-blocking layer in the plan view.

In an embodiment, the electronic device may further include a display module, a processor, a power module, and a memory, wherein the display device may include one of the display module, the processor, the power module, or the memory.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view of a display device according to an embodiment;

FIG. 2 is a schematic view of the configuration of a display device according to an embodiment;

FIG. 3 is an equivalent circuit diagram of a pixel according to an embodiment;

FIG. 4 is a schematic plan view of a display area of a display device according to an embodiment;

FIG. 5 is an enlarged plan view of a portion of the display area of FIG. 4;

FIG. 6 is an enlarged plan view of a portion of the display area of FIG. 4;

FIGS. 7A and 7B are respectively schematic cross-sectional views of a first display area and a second display area of a display device according to an embodiment; and

FIGS. 8A and 8B are respectively schematic cross-sectional views of a first display area and a second display area of a display device according to an embodiment.

FIG. 9 is a block diagram of an electronic device according to an embodiment.

FIG. 10 is a schematic diagrams of electronic devices according to various embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, particular embodiments will be illustrated in the drawings and described in detail in the written description. Effects and features of the disclosure and methods of achieving the same will be apparent with reference to embodiments and drawings described below in detail. The disclosure may, however, be embodied in many different forms and should not be construed as being limited to the embodiments set forth herein.

Hereinafter, embodiments of the disclosure will be described in detail with reference to the accompanying drawings, and in the description with reference to the drawings, the same or corresponding components are indicated by the same reference numerals and redundant descriptions thereof are omitted.

In the present specification, although terms such as “first” and “second” may be used to describe various components, these components should not be limited by these terms. These terms are only used to distinguish one component from another.

In the present specification, the expression of singularity includes the expression of plurality unless clearly specified otherwise in context.

In the present specification, terms such as “comprise,” “comprising,” “include,” and/or “including” specify the presence of stated features or components, but do not preclude the presence or addition of one or more other features or components.

In the present specification, it will be understood that when a layer, region, or component is referred to as being “on” or “above” another layer, region, or component, it can be directly or indirectly on or above the other layer, region, or component. That is, for example, intervening layers, regions, or components may be present.

In the present specification, it will be understood that when a layer, region, or component is referred to as being “connected” to another layer, region, or component, it can be directly and/or indirectly connected to the other layer, region, or component. That is, for example, intervening layers, regions, or components may be present. For example, in the present specification, it will be understood that when a layer, region, or component is referred to as being “electrically connected” to another layer, region, or component, it can be directly and/or indirectly electrically connected to the other layer, region, or component. That is, for example, intervening layers, regions, or components may be present.

In the present specification, the expression “A and/or B” represents A, B, or A and B. In addition, the expression “at least one of A and B” represents A, B, or A and B.

In the present specification, the x-axis, the y-axis, and the z-axis are not limited to three axes of the rectangular coordinate system and may be interpreted in a broader sense. For example, the x-axis, the y-axis, and the z-axis may be perpendicular to one another or may represent different directions that are not perpendicular to one another.

Sizes of components in the drawings may be exaggerated for convenience of description. In other words, because sizes and thicknesses of components in the drawings are arbitrarily illustrated for convenience of explanation, the following embodiments are not limited thereto.

“Substantially the same” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “Substantially the same” can mean within one or more standard deviations, or within ±10%, 5% or 2% of the stated value (e.g., thickness, distance, area, etc.).

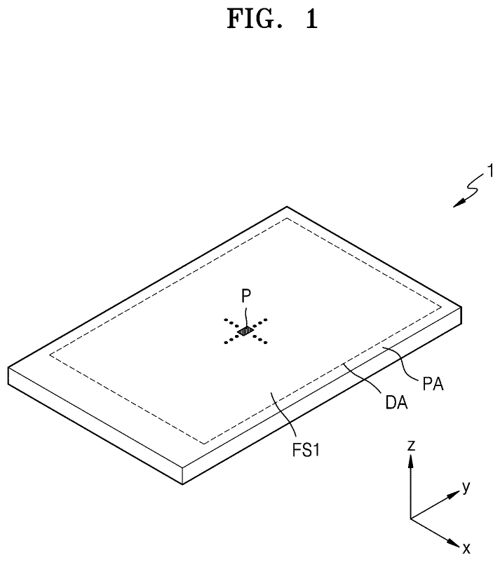

FIG. 1 is a schematic perspective view of a display device 1 according to an embodiment.

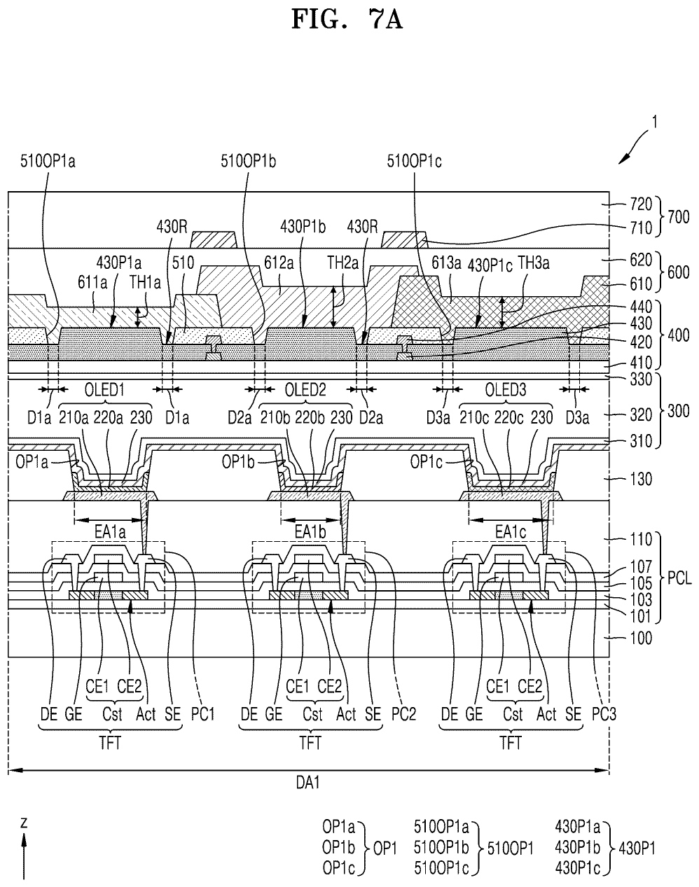

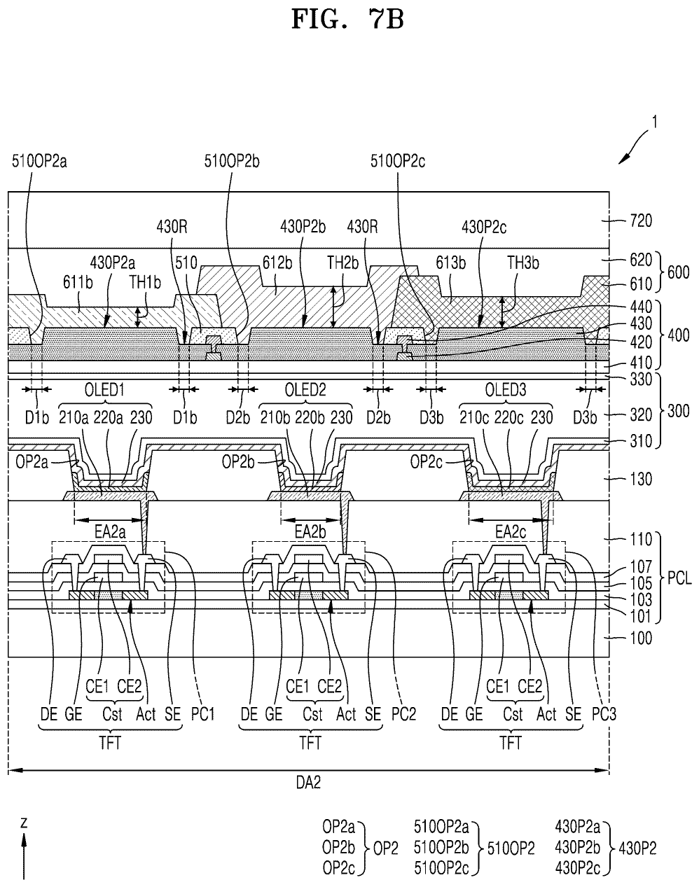

Referring to FIG. 1, the display device 1 may include a display area DA and a peripheral area PA. The display device 1 may include a substrate 100 and a multi-layer film on the substrate 100, as will be described with reference to FIG. 7A, and thus, the substrate 100 of the display device 1 may be understood as including the display area DA and the peripheral area PA.

A subpixel P may be disposed in the display area DA. In an embodiment, the subpixel P may be disposed on a front surface FS1 of the display device 1.

In an embodiment, a plurality of subpixels P may be disposed in the display area DA. The subpixel P may be implemented by a display element. The display device 1 may provide an image by using light emitted from the subpixel P. In an embodiment, the light emitted from the subpixel P may travel in a direction perpendicular to the front surface FS1 of the display device 1 (e.g., a z-direction) and/or in a direction substantially perpendicular to the front surface FS1 of the display device 1. In an embodiment, the light emitted from the subpixel P may travel in a direction oblique to the front surface FS1 of the display device 1 (e.g., a direction crossing the z-direction).

In an embodiment, the subpixel P may emit red, green, or blue light by using a display element. In an embodiment, the subpixel P may emit red, green, blue, or white light by using a display element. In an embodiment, the subpixel P may be defined as an emission area of a display element that emits light of any one of red, green, blue, and white. In this case, a plurality of subpixels P may be provided, and the plurality of subpixels P may be disposed apart from each other. Also, some of the plurality of subpixels P, some other of the plurality of subpixels P, and still some other of the plurality of subpixels P may emit different colors.

The subpixel P may include a light-emitting diode as a display element capable of emitting light of a certain color. The light-emitting diode may include an organic light-emitting diode including an organic material in an emission layer. Alternatively, the light-emitting diode may include an inorganic light-emitting diode. Alternatively, the light-emitting diode may include quantum dots in an emission layer. In an embodiment, the size of the light-emitting diode may be micro-scale or nano-scale. For example, the light-emitting diode may include a micro-light-emitting diode. Alternatively, the light-emitting diode may include a nano-light-emitting diode. The nano-light-emitting diode may include gallium nitride (GaN). In an embodiment, a color conversion layer may be disposed on the nano-light-emitting diode. The color conversion layer may include quantum dots. Hereinafter, for convenience of description, a case in which the light-emitting diode includes an organic light-emitting diode will be mainly described.

The peripheral area PA may be an area that does not provide an image. The peripheral area PA may at least partially surround the display area DA. In an embodiment, the peripheral area PA may entirely surround the display area DA. A driver or the like for providing an electrical signal or power to the subpixel P may be disposed in the peripheral area PA. Also, the peripheral area PA may include a pad area in which a pad is disposed.

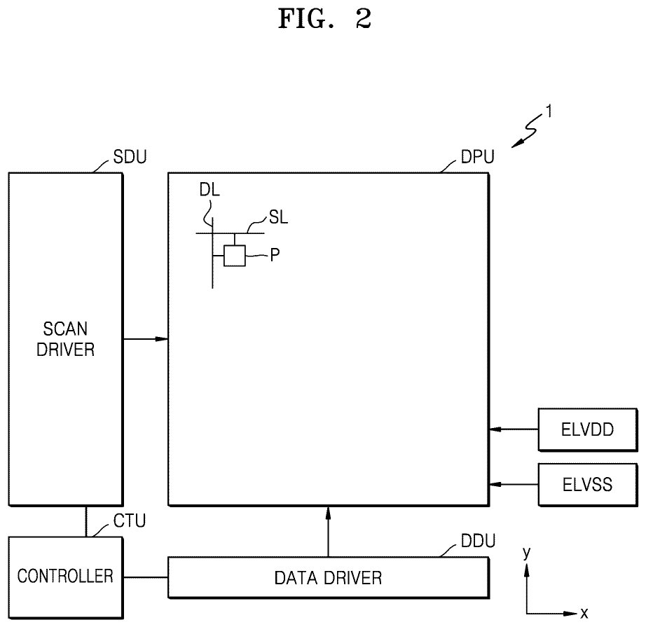

FIG. 2 is a schematic view of the configuration of the display device 1 according to an embodiment.

Referring to FIG. 2, the display device 1 may include a display DPU, a scan driver SDU, a data driver DDU, and a controller CTU.

The display DPU may be disposed in the display area DA described with reference to FIG. 1. A plurality of subpixels P and signal lines configured to apply electrical signals to the plurality of subpixels P may be disposed in the display DPU.

The plurality of subpixels P may be repeatedly arranged in a first direction (e.g., an x-direction) and a second direction (e.g., a y-direction). The plurality of subpixels P may be arranged in various forms, such as a stripe arrangement, a pentile arrangement, or a mosaic arrangement, to implement an image.

The signal lines configured to apply electrical signals to the plurality of subpixels P may include a plurality of scan lines SL extending in the first direction, a plurality of data lines DL extending in the second direction, and the like. The plurality of scan lines SL may be disposed apart from each other in the second direction and may be configured to transmit scan signals to the subpixels P. The plurality of data lines DL may be disposed apart from each other in the first direction and may be configured to transmit data signals to the subpixels P. Each of the plurality of subpixels P may be connected to at least one corresponding scan line SL, from among the plurality of scan lines SL, and at least one corresponding data line DL, from among the plurality of data lines DL.

When the display device 1 is an organic electroluminescent display device, a first power voltage ELVDD and a second power voltage ELVSS may be supplied to the subpixels P of the display DPU. The first power voltage ELVDD may be a high-level voltage provided to a first electrode (a pixel electrode or an anode) of a display element included in each subpixel P. The second power voltage ELVSS may be a low-level voltage provided to a second electrode (a common electrode or a cathode) of a display element included in each subpixel P. The first power voltage ELVDD and the second power voltage ELVSS may be driving voltages for causing the plurality of subpixels P to emit light.

The scan driver SDU, the data driver DDU, and the controller CTU may be disposed in the peripheral area PA described with reference to FIG. 1.

The scan driver SDU may be connected to the plurality of scan lines SL, may generate scan signals in response to a scan control signal from the controller CTU, and may sequentially supply the generated scan signals to the scan lines SL.

The data driver DDU may be connected to the plurality of data lines DL and may supply data signals to the data lines DL in response to a data control signal from the controller CTU.

The controller CTU may generate a scan control signal and a data control signal based on signals input from the outside. The controller CTU may supply a scan control signal to the scan driver SDU and may supply a data control signal to the data driver DDU.

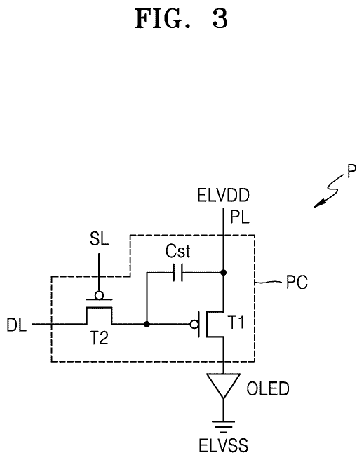

FIG. 3 is an equivalent circuit diagram of the subpixel P according to an embodiment.

Referring to FIG. 3, the subpixel P may include a pixel circuit PC and an organic light-emitting diode OLED as a display element.

The pixel circuit PC may include a driving thin-film transistor T1, a switching thin-film transistor T2, and a storage capacitor Cst. Each subpixel P may emit red, green, or blue light, or emit red, green, blue, or white light, through the organic light-emitting diode OLED.

The switching thin-film transistor T2 may be connected to the scan line SL and the data line DL and may transmit a data signal or a data voltage input from the data line DL, to the driving thin-film transistor T1, based on a scan signal or a switching voltage input from the scan line SL. The storage capacitor Cst may be connected to the switching thin-film transistor T2 and a driving voltage line PL and may store a voltage corresponding to a difference between a voltage received from the switching thin-film transistor T2 and the first power voltage ELVDD supplied to the driving voltage line PL.

The driving thin-film transistor T1 may be connected to the driving voltage line PL and the storage capacitor Cst and may control a driving current flowing from the driving voltage line PL to the organic light-emitting diode OLED, in response to a voltage value stored in the storage capacitor Cst. The organic light-emitting diode OLED may emit light having a certain luminance according to the driving current. A common electrode (e.g., a cathode) of the organic light-emitting diode OLED may receive the second power voltage ELVSS.

Although the pixel circuit PC includes two transistors and one capacitor in FIG. 3, the disclosure is not limited thereto. The number of transistors and the number of capacitors may be variously modified according to the design of the pixel circuit PC.

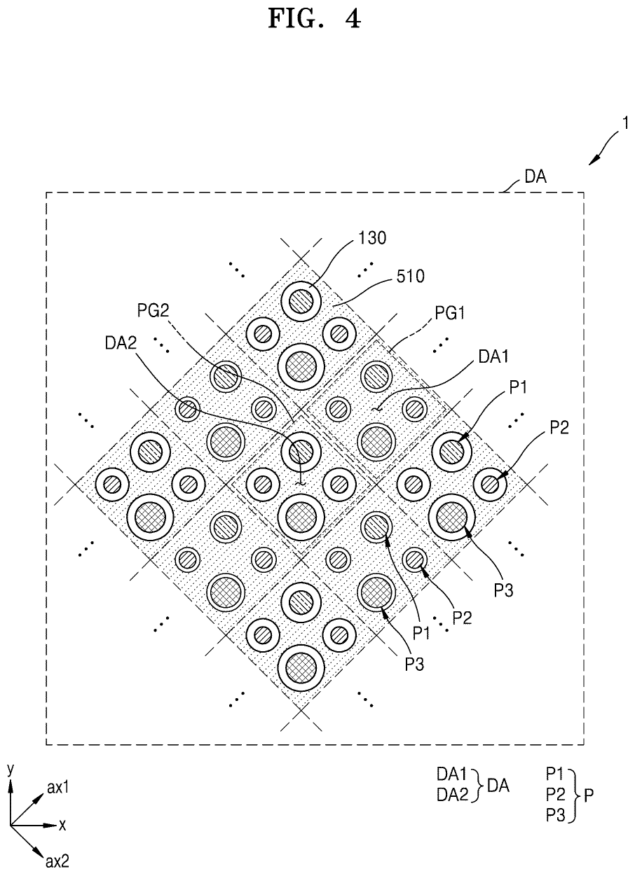

FIG. 4 is a schematic plan view of the display area DA of the display device 1 according to an embodiment. As used herein, the “plan view” is a view in a thickness direction (i.e., z-direction) of a substrate 100.

Referring to FIG. 4, the display area DA may include a first display area DA1 and a second display area DA2. A plurality of subpixels P may be disposed in each of the first display area DA1 and the second display area DA2. For example, a first subpixel group PG1 including a plurality of subpixels P may be disposed in the first display area DA1, and a second subpixel group PG2 including a plurality of subpixels P may be disposed in the second display area DA2. The subpixel P may include a first subpixel P1 emitting light of a first wavelength, a second subpixel P2 emitting light of a second wavelength, and a third subpixel P3 emitting light of a third wavelength. In an embodiment, the first subpixel P1 may emit red light, the second subpixel P2 may emit green light, and the third subpixel P3 may emit blue light. In an embodiment, each of the first subpixel group PG1 and the second subpixel group PG2 may include two second subpixels P2, one first subpixel P1, and one third subpixel P3.

The display device 1 may operate in various ways. For example, the display device 1 may operate in a normal driving mode (e.g., a first mode) or a private driving mode (e.g., a second mode). The normal driving mode may be a mode that provides a wide viewing angle in all directions. The private driving mode may be a mode that provides a narrow viewing angle in at least some directions and may be a mode in which side visibility is reduced or blocked, compared to the normal driving mode. While the display device 1 operates in the private driving mode, the viewing angle of another person, who views the display device 1 from the side, may be reduced or the other person's view may be blocked, and thus, personal information exposure may be prevented.

When the controller CTU (see FIG. 2) receives a selection signal for selecting the normal driving mode or the private driving mode, the controller CTU may output a control signal to the scan driver SDU (see FIG. 2) and the data driver DDU (see FIG. 2) so that the display device 1 operates in the normal driving mode or the private driving mode according to the selection signal.

In the normal driving mode, both the first display area DA1 and the second display area DA2 may operate to implement an image. In the normal driving mode, both the first subpixel group PG1 disposed in the first display area DA1 and the second subpixel group PG2 disposed in the second display area DA2 may operate. In the normal driving mode, all of the first to third subpixels P1, P2, and P3 constituting the first subpixel group PG1 of the first display area DA1 and the first to third subpixels P1, P2, and P3 constituting the second subpixel group PG2 of the second display area DA2 may be selected by a scan signal and may emit light with a luminance corresponding to a corresponding data signal.

In contrast, in the private driving mode, only the first display area DA1 may operate to implement an image. In the private driving mode, the first subpixel group PG1 disposed in the first display area DA1 may operate, and the second subpixel group PG2 disposed in the second display area DA2 may not operate. In the private driving mode, the first to third subpixels P1, P2, and P3 constituting the first subpixel group PG1 of the first display area DA1 may not emit light, and the first to third subpixels P1, P2, and P3 constituting the second subpixel group PG2 of the second display area DA2 may emit light with a luminance corresponding to a data signal. Here, the non-emission of a subpixel may include a case in which the subpixel is not selected by a scan signal and thus does not receive a data signal, or a case in which the subpixel is selected by a scan signal, but receives a black data signal and thus expresses a black color.

In an embodiment, a plurality of first display areas DA1 and a plurality of second display areas DA2 may be provided. In an embodiment, the plurality of first display areas DA1 and the plurality of second display areas DA2 may be alternately disposed in a third direction ax1 and a fourth direction ax2 that cross the first direction (e.g., the x-direction) and the second direction (e.g., the y-direction). In an embodiment, the third direction ax1 and the fourth direction ax2 may be perpendicular to each other. In another embodiment, the third direction ax1 and the fourth direction ax2 may form an acute angle or an obtuse angle with each other. In the display area DA, the first display area DA1 in which the first subpixel group PG1 is disposed and the second display area DA2 in which the second subpixel group PG2 is disposed may be repeated in the third direction ax1 and the fourth direction ax2.

In an embodiment, each of the first subpixel group PG1 and the second subpixel group PG2 may have a shape in which two second subpixels P2, one first subpixel P1, and one third subpixel P3 are grouped in a quadrangle. The first subpixel group PG1 and the second subpixel group PG2 are divided into repeating shapes and do not mean a structural disconnection.

When the arrangement structure of the display area DA is expressed differently, any one of the plurality of first display areas DA1 may be surrounded by the plurality of second display areas DA2. Any one of the plurality of second display areas DA2 may be surrounded by the plurality of first display areas DA1.

The size (area) of the first display area DA1 may be the same as or different from the size (area) of the second display area DA2. FIG. 4 shows an example in which the size (area) of the first display area DA1 is the same as the size (area) of the second display area DA2.

In an embodiment, the arrangement of the first subpixel P1, the second subpixel P2, and the third subpixel P3 constituting the first subpixel group PG1 may be the same as the arrangement of the first subpixel P1, the second subpixel P2, and the third subpixel P3 constituting the second subpixel group PG2.

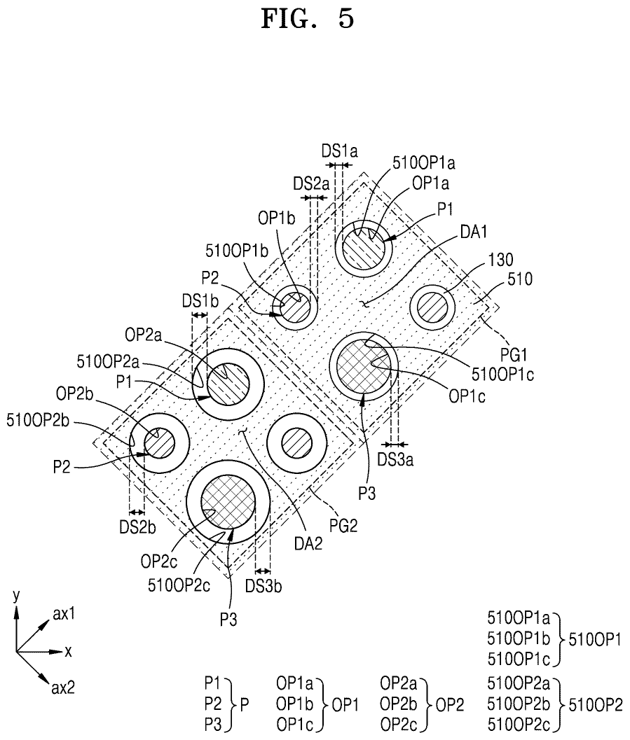

FIG. 5 is an enlarged plan view of a portion of the display area DA of FIG. 4. FIG. 5 shows an enlarged view of the first display area DA1 and the second display area DA2.

Referring to FIG. 5, a pixel-defining layer 130 may define a first pixel opening OP1 therein defining an emission area of the subpixel P of the first subpixel group PG1 disposed in the first display area DA1, and a second pixel opening OP2 therein defining an emission area of the subpixel P of the second subpixel group PG2 disposed in the second display area DA2. For example, the pixel-defining layer 130 may have a first-1 pixel opening OP1a, a first-2 pixel opening OP1b, and a first-3 pixel opening OP1c that define emission areas of the first subpixel P1, the second subpixel P2, and the third subpixel P3 of the first subpixel group PG1, respectively. For example, the pixel-defining layer 130 may have a second-1 pixel opening OP2a, a second-2 pixel opening OP2b, and a second-3 pixel opening OP2c that define emission areas of the first subpixel P1, the second subpixel P2, and the third subpixel P3 of the second subpixel group PG2, respectively.

In an embodiment, emission areas that emit light of the same wavelength may have substantially the same size (area). For example, the size (area) of the emission area of the first subpixel P1 of the first subpixel group PG1 may be substantially the same as the size (area) of the emission area of the first subpixel P1 of the second subpixel group PG2. For example, the size (area) of the emission area of the second subpixel P2 of the first subpixel group PG1 may be substantially the same as the size (area) of the emission area of the second subpixel P2 of the second subpixel group PG2. For example, the size (area) of the emission area of the third subpixel P3 of the first subpixel group PG1 may be substantially the same as the size (area) of the emission area of the third subpixel P3 of the second subpixel group PG2.

In an embodiment, the emission areas of the first to third subpixels P1, P2, and P3 may have different sizes (areas). For example, the size (area) of the emission area of the first subpixel P1 may be greater than the size (area) of the emission area of the second subpixel P2 and less than the size (area) of the emission area of the third subpixel P3. For example, the size (area) of the emission area of the second subpixel P2 may be less than the sizes (areas) of the emission area of the first subpixel P1 and the emission area of the third subpixel P3. For example, the size (area) of the emission area of the third subpixel P3 may be greater than the sizes (areas) of the emission area of the first subpixel P1 and the emission area of the second subpixel P2.

A first light-blocking layer 510 may define a first opening 510OP1 overlapping the emission area of the subpixel P of the first subpixel group PG1 disposed in the first display area DA1, and a second opening 510OP2 overlapping the emission area of the subpixel P of the second subpixel group PG2 disposed in the second display area DA2 in a plan view. Each of the first opening 510OP1 and the second opening 510OP2 of the first light-blocking layer 510 may be defined as a transmission area of the subpixel P through which light emitted from the emission area of the subpixel P passes. For example, the first light-blocking layer 510 may have a first-1 opening 510OP1a, a first-2 opening 510OP1b, and a first-3 opening 510OP1c that overlap the emission areas of the first subpixel P1, the second subpixel P2, and third subpixel P3 of the first subpixel group PG1, respectively. That is, the first-1 opening 510OP1a, the first-2 opening 510OP1b, and the first-3 opening 510OP1c of the first light-blocking layer 510 may overlap the first-1 pixel opening OP1a, the first-2 pixel opening OP1b, and the first-3 pixel opening OP1c, respectively. For example, the first light-blocking layer 510 may have a second-1 opening 510OP2a, a second-2 opening 510OP2b, and a second-3 opening 510OP2c that overlap the emission areas of the first subpixel P1, the second subpixel P2, and third subpixel P3 of the second subpixel group PG2, respectively. That is, the second-1 opening 510OP2a, the second-2 opening 510OP2b, and the second-3 opening 510OP2c of the first light-blocking layer 510 may overlap the second-1 pixel opening OP2a, the second-2 pixel opening OP2b, and the second-3 pixel opening OP2c, respectively, in a plan view.

The sizes (areas) of transmission areas of the first subpixel P1, the second subpixel P2, and the third subpixel P3 in the first subpixel group PG1 may be less than the sizes (areas) of corresponding transmission areas of the first subpixel P1, the second subpixel P2, and third subpixel P3 in the second subpixel group PG2, respectively. For example, the size (area) of the first-1 opening 510OP1a of the first light-blocking layer 510, which is the transmission area of the first subpixel P1 of the first subpixel group PG1, may be less than the size (area) of the second-1 opening 510OP2a of the first light-blocking layer 510, which is the transmission area of the first subpixel P1 of the second subpixel group PG2. For example, the size (area) of the first-2 opening 510OP1b of the first light-blocking layer 510, which is the transmission area of the second subpixel P2 of the first subpixel group PG1, may be less than the size (area) of the second-2 opening 510OP2b of the first light-blocking layer 510, which is the transmission area of the second subpixel P2 of the second subpixel group PG2. For example, the size (area) of the first-3 opening 510OP1c of the first light-blocking layer 510, which is the transmission area of the third subpixel P3 of the first subpixel group PG1, may be less than the size (area) of the second-3 opening 510OP2c of the first light-blocking layer 510, which is the transmission area of the third subpixel P3 of the second subpixel group PG2.

In a plan view, a minimum distance between the emission area of the subpixel P in the first subpixel group PG1 and the first light-blocking layer 510 may be less than a minimum distance between the emission area of the subpixel P in the second subpixel group PG2 and the first light-blocking layer 510. In other words, in a plan view, a minimum distance between the first pixel opening OP1 of the pixel-defining layer 130 and the first light-blocking layer 510 in the first display area DA1 may be less than a minimum distance between the second pixel opening OP2 of the pixel-defining layer 130 and the first light-blocking layer 510 in the second display area DA2. For example, in a plan view, a minimum distance DS1a between the first-1 pixel opening OP1a and the first light-blocking layer 510 in the first display area DA1 may be less than a minimum distance DS1b between the second-1 pixel opening OP2a and the first light-blocking layer 510 in the second display area DA2. For example, in a plan view, a minimum distance DS2a between the first-2 pixel opening OP1b and the first light-blocking layer 510 in the first display area DA1 may be less than a minimum distance DS2b between the second-2 pixel opening OP2b and the first light-blocking layer 510 in the second display area DA2. For example, in a plan view, a minimum distance DS3a between the first-3 pixel opening OP1c and the first light-blocking layer 510 in the first display area DA1 may be less than a minimum distance DS3b between the second-3 pixel opening OP2c and the first light-blocking layer 510 in the second display area DA2.

Each of the first pixel opening OP1 and the second pixel opening OP2 is shown as having a circular shape, but is not limited thereto. For example, each of the first pixel opening OP1 and the second pixel opening OP2 may have a circular shape, an oval shape, or a polygonal shape. Here, the polygonal shape may include a square, a rectangle, and a diamond and may have round corners.

Each of the first opening 510OP1 and the second opening 510OP2 of the first light-blocking layer 510 is shown as having a circular shape, but is not limited thereto. For example, each of the first opening 510OP1 and the second opening 510OP2 of the first light-blocking layer 510 may have a circular shape, an oval shape, or a polygonal shape. Here, the polygonal shape may include a square, a rectangle, and a diamond and may have round corners.

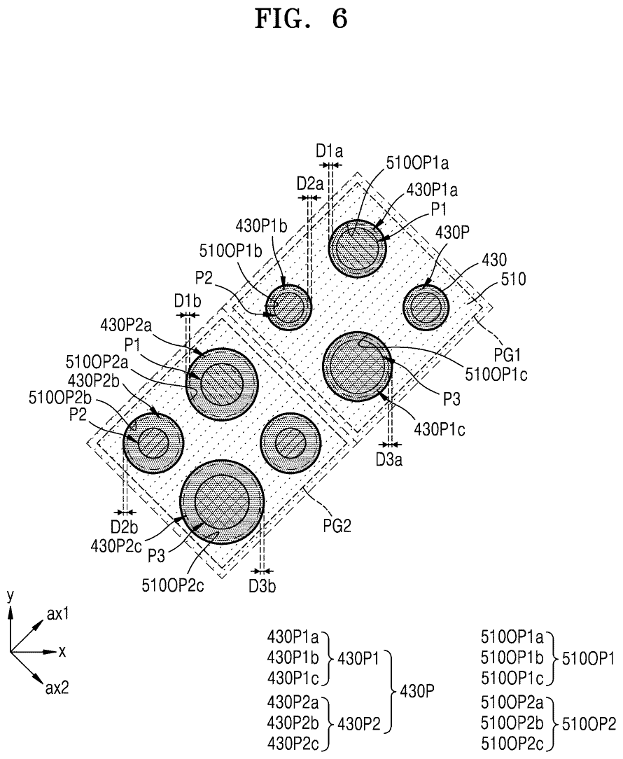

FIG. 6 is an enlarged plan view of a portion of the display area DA of FIG. 4. FIG. 6 shows an enlarged view of the first display area DA1 and the second display area DA2, like to FIG. 5, but also shows the arrangement of a touch insulating layer 430.

Referring to FIG. 6, the touch insulating layer 430 may be disposed on the pixel-defining layer 130 (see FIG. 5). The touch insulating layer 430 may include protrusions 430P and a recess 430R (see FIGS. 7A and 7B) defined by the protrusions 430P.

The protrusions 430P of the touch insulating layer 430 may respectively overlap the emission areas of the first to third subpixels P1, P2, and P3 of the first subpixel group PG1 and the emission areas of the first to third subpixels P1, P2, and P3 of the second subpixel group PG2. For example, the touch insulating layer 430 may include first protrusions 430P1 that respectively overlap the emission areas of the first to third subpixels P1, P2, and P3 of the first subpixel group PG1, and second protrusions 430P2 that respectively overlap the emission areas of the first to third subpixels P1, P2, and P3 of the second subpixel group PG2. For example, the emission areas of the first subpixel P1, the second subpixel P2, and the third subpixel P3 of the first subpixel group PG1 may respectively overlap a first-1 protrusion 430P1a, a first-2 protrusion 430P1b, and a first-3 protrusion 430P1c. For example, the emission areas of the first subpixel P1, the second subpixel P2, and the third subpixel P3 of the second subpixel group PG2 may respectively overlap a second-1 protrusion 430P2a, a second-2 protrusion 430P2b, and a second-3 protrusion 430P2c in a plan view.

The first light-blocking layer 510 may not overlap the protrusions 430P of the touch insulating layer 430. The first light-blocking layer 510 may be disposed on the recess 430R (see FIGS. 7A and 7B) of the touch insulating layer 430. The first light-blocking layer 510 may be disposed in a groove defined by side surfaces of the protrusions 430P of the touch insulating layer 430 and an upper surface of the recess 430R of the touch insulating layer 430. The first light-blocking layer 510 may not overlap the emission areas of the first to third subpixels P1, P2, and P3 of the first subpixel group PG1 and the emission areas of the first to third subpixels P1, P2, and P3 of the second subpixel group PG2 in a plan view.

In a plan view, the size (area) of the first opening 510OP1 of the first light-blocking layer 510 may be greater than the size (area) of the first protrusion 430P1 disposed corresponding to the first opening 510OP1. For example, in a plan view, the size (area) of the first-1 opening 510OP1a of the first light-blocking layer 510 may be greater than the size (area) of the first-1 protrusion 430P1a. For example, in a plan view, the size (area) of the first-2 opening 510OP1b of the first light-blocking layer 510 may be greater than the size (area) of the first-2 protrusion 430P1b. For example, in a plan view, the size (area) of the first-3 opening 510OP1c of the first light-blocking layer 510 may be greater than the size (area) of the first-3 protrusion 430P1c.

In a plan view, the size (area) of the second opening 510OP2 of the first light-blocking layer 510 may be greater than the size (area) of the second protrusion 430P2 disposed corresponding to the second opening 510OP2. For example, in a plan view, the size (area) of the second-1 opening 510OP2a of the first light-blocking layer 510 may be greater than the size (area) of the second-1 protrusion 430P2a. For example, in a plan view, the size (area) of the second-2 opening 510OP2b of the first light-blocking layer 510 may be greater than the size (area) of the second-2 protrusion 430P2b. For example, in a plan view, the size (area) of the second-3 opening 510OP2c of the first light-blocking layer 510 may be greater than the size (area) of the second-3 protrusion 430P2c.

In a plan view, a minimum distance between the first light-blocking layer 510 and the first protrusion 430P1 overlapping the emission area of any one subpixel P of the first subpixel group PG1 may be substantially the same as a minimum distance between the first light-blocking layer 510 and the second protrusion 430P2 overlapping the emission area of the corresponding subpixel P of the second subpixel group PG2. For example, in a plan view, a minimum distance D1a between the first light-blocking layer 510 and the first-1 protrusion 430P1a overlapping the emission area of the first subpixel P1 of the first subpixel group PG1 may be substantially the same as a minimum distance D1b between the first light-blocking layer 510 and the second-1 protrusion 430P2a overlapping the emission area of the first subpixel P1 of the second subpixel group PG2. For example, in a plan view, a minimum distance D2a between the first light-blocking layer 510 and the first-2 protrusion 430P1b overlapping the emission area of the second subpixel P2 of the first subpixel group PG1 may be substantially the same as a minimum distance D2b between the first light-blocking layer 510 and the second-2 protrusion 430P2b overlapping the emission area of the second subpixel P2 of the second subpixel group PG2. For example, in a plan view, a minimum distance D3a between the first light-blocking layer 510 and the first-3 protrusion 430P1c overlapping the emission area of the third subpixel P3 of the first subpixel group PG1 may be substantially the same as a minimum distance D3b between the first light-blocking layer 510 and the second-3 protrusion 430P2c overlapping the emission area of the third subpixel P3 of the second subpixel group PG2 in a plan view.

In an embodiment, in a plan view, the size (area) of the first protrusion 430P1 overlapping the emission area of any one subpixel P of the first subpixel group PG1 may be less than the size (area) of the second protrusion 430P2 overlapping the emission area of the corresponding subpixel P of the second subpixel group PG2. For example, in a plan view, the size (area) of the first-1 protrusion 430P1a overlapping the emission area of the first subpixel P1 of the first subpixel group PG1 may be less than the size (area) of the second-1 protrusion 430P2a overlapping the emission area of the corresponding first subpixel P1 of the second subpixel group PG2 in a plan view.

In an embodiment, the first-1 protrusion 430P1a, the first-2 protrusion 430P1b, and the first-3 protrusion 430P1c may have different sizes (areas). For example, the size (area) of the first-1 protrusion 430P1a may be greater than the size (area) of the first-2 protrusion 430P1b and less than the size (area) of the first-3 protrusion 430P1c. For example, the size (area) of the first-2 protrusion 430P1b may be less than the size (area) of the first-1 protrusion 430P1a and the size (area) of the first-3 protrusion 430P1c. For example, the size (area) of the first-3 protrusion 430P1c may be greater than the size (area) of the first-1 protrusion 430P1a and the size (area) of the first-2 protrusion 430P1b.

In an embodiment, the second-1 protrusion 430P2a, the second-2 protrusion 430P2b, and the second-3 protrusion 430P2c may have different sizes (areas). For example, the size (area) of the second-1 protrusion 430P2a may be greater than the size (area) of the second-2 protrusion 430P2b and less than the size (area) of the second-3 protrusion 430P2c. For example, the size (area) of the second-2 protrusion 430P2b may be less than the size (area) of the second-1 protrusion 430P2a and the size (area) of the second-3 protrusion 430P2c. For example, the size (area) of the second-3 protrusion 430P2c may be greater than the size (area) of the second-1 protrusion 430P2a and the size (area) of the second-2 protrusion 430P2b.

Each of the protrusions 430P of the touch insulating layer 430 is shown as having a circular shape, but is not limited thereto. For example, each of the protrusions 430P of the touch insulating layer 430 may have a circular shape, an oval shape, or a polygonal shape. Here, the polygonal shape may include a square, a rectangle, and a diamond and may have round corners.

FIGS. 7A and 7B are respectively schematic cross-sectional views of the first display area DA1 and the second display area DA2 of the display device 1 according to an embodiment. FIGS. 7A and 7B are cross-sectional views of the display device 1 according to an embodiment described with reference to FIGS. 4 to 6.

Referring to FIGS. 7A and 7B, the display device 1 may include the substrate 100, a pixel circuit layer PCL, first to third organic light-emitting diodes OLED1, OLED2, and OLED3, an encapsulation member 300, an input sensing layer 400, the first light-blocking layer 510, an anti-reflection layer 600, and an optical functional layer 700.

FIG. 7A shows the first organic light-emitting diode OLED1, the second organic light-emitting diode OLED2, and the third organic light-emitting diode OLED3 that are respectively included in the first subpixel P1 (see FIG. 4), the second subpixel P2 (see FIG. 4), and the third subpixel P3 (see FIG. 4) of the first subpixel group PG1 disposed in the first display area DA1, and a first pixel circuit PC1, a second pixel circuit PC2, and a third pixel circuit PC3 that are respectively electrically connected to the first organic light-emitting diode OLED1, the second organic light-emitting diode OLED2, and the third organic light-emitting diode OLED3.

FIG. 7B shows the first organic light-emitting diode OLED1, the second organic light-emitting diode OLED2, and the third organic light-emitting diode OLED3 that are respectively included in the first subpixel P1 (see FIG. 4), the second subpixel P2 (see FIG. 4), and the third subpixel P3 (see FIG. 4) of the second subpixel group PG2 disposed in the second display area DA2, and the first pixel circuit PC1, the second pixel circuit PC2, and the third pixel circuit PC3 that are respectively electrically connected to the first organic light-emitting diode OLED1, the second organic light-emitting diode OLED2, and the third organic light-emitting diode OLED3.

The substrate 100 may include glass or polymer resin, such as polyethersulfone, polyarylate, polyetherimide, polyethylene naphthalate, polyethylene terephthalate, polyphenylene sulfide, polyimide, polycarbonate, cellulose triacetate, or cellulose acetate propionate. In an embodiment, the substrate 100 may have a multi-layer structure including a base layer including the above-described polymer resin, and a barrier layer (not shown). The substrate 100 including the polymer resin may be flexible, rollable, or bendable.

The pixel circuit layer PCL may include the first to third pixel circuits PC1, PC2, and PC3 and insulating layers. Each of the first to third pixel circuits PC1, PC2, and PC3 may include a thin-film transistor and a storage capacitor as described above with reference to FIG. 3. In an embodiment, FIGS. 7A and 7B show a thin-film transistor TFT and the storage capacitor Cst provided in each of the first to third pixel circuits PC1, PC2, and PC3.

The pixel circuit layer PCL may include a buffer layer 101, a first gate insulating layer 103, a second gate insulating layer 105, an interlayer insulating layer 107, the thin-film transistor TFT, and a via insulating layer 110.

The buffer layer 101 may be disposed on the substrate 100 to planarize an upper surface of the substrate 100. The buffer layer 101 may block impurities, moisture, or external gas from entering the display device 1 from the outside. The buffer layer 101 may include an inorganic insulating material, such as silicon oxide (SiOₓ), silicon nitride (SiNₓ), and silicon oxynitride (SiOₓN_{y}). The buffer layer 101 may include a single-layer or multi-layer structure including the above-described inorganic insulating material.

Each of the first to third pixel circuits PC1, PC2, and PC3 may include at least one thin-film transistor TFT and at least one storage capacitor Cst. The thin-film transistor TFT may include a semiconductor layer Act, a gate electrode GE, a source electrode SE, and a drain electrode DE.

The semiconductor layer Act may be disposed on the buffer layer 101. The semiconductor layer Act may include an oxide semiconductor and/or a silicon semiconductor. When the semiconductor layer Act includes an oxide semiconductor, the semiconductor layer Act may include, for example, an oxide of at least one material selected from among indium (In), gallium (Ga), tin (Sn), zirconium (Zr), vanadium (V), hafnium (Hf), cadmium (Cd), germanium (Ge), chromium (Cr), titanium (Ti), and zinc (Zn). For example, the semiconductor layer Act may be an InSnZnO (ITZO) semiconductor layer, an InGaZnO (IGZO) semiconductor layer, or the like. When the semiconductor layer Act includes a silicon semiconductor, the semiconductor layer Act may include, for example, amorphous silicon or low-temperature poly-silicon (LTPS). A barrier layer for blocking or reducing penetration of external air may be further included between the substrate 100 and the buffer layer 101.

The first gate insulating layer 103 may be disposed on the buffer layer 101. The first gate insulating layer 103 may be disposed on the semiconductor layer Act. The first gate insulating layer 103 may include, for example, an inorganic insulating material, such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO).

The gate electrode GE may be disposed on the semiconductor layer Act. The first gate insulating layer 103 may be disposed between the gate electrode GE and the semiconductor layer Act. The gate electrode GE may overlap a channel region of the semiconductor layer Act. The gate electrode GE may include a low-resistance metal material. For example, the gate electrode GE may be formed as a single layer or multi-layer including at least one metal selected from among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). The gate electrode GE may be connected to a gate line configured to apply an electrical signal to the gate electrode GE.

The second gate insulating layer 105 may be disposed on the first gate insulating layer 103. The second gate insulating layer 105 may cover the gate electrode GE. Like the first gate insulating layer 103, the second gate insulating layer 105 may include an inorganic insulating material, such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO).

A second capacitor electrode CE2 of the storage capacitor Cst may be disposed on the second gate insulating layer 105. In an embodiment, the second capacitor electrode CE2 may overlap the gate electrode GE. The second gate insulating layer 105 may be disposed between the gate electrode GE and the second capacitor electrode CE2. The gate electrode GE and the second capacitor electrode CE2 that overlap each other may constitute the storage capacitor Cst. That is, the gate electrode GE may function as a first capacitor electrode CE1 of the storage capacitor Cst. As shown in FIGS. 7A and 7B, the storage capacitor Cst and the thin-film transistor TFT may overlap each other, but are not limited thereto. In another embodiment, the storage capacitor Cst and the thin-film transistor TFT may not overlap each other in a plan view.

The interlayer insulating layer 107 may be disposed on the second gate insulating layer 105. The interlayer insulating layer 107 may cover the second capacitor electrode CE2. The interlayer insulating layer 107 may include an inorganic insulating material, such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO). The interlayer insulating layer 107 may be a single layer or multi-layer including the above-described inorganic insulating material.

Each of the source electrode SE and the drain electrode DE may be disposed on the interlayer insulating layer 107. Each of the source electrode SE and the drain electrode DE may be electrically connected to the semiconductor layer Act through a contact hole formed in the first gate insulating layer 103, the second gate insulating layer 105, and the interlayer insulating layer 107. Each of the source electrode SE and the drain electrode DE may include a material having excellent conductivity. At least one of the source electrode SE and the drain electrode DE may include a conductive material including molybdenum (Mo), aluminum (AI), copper (Cu), or titanium (Ti) and may be a multi-layer or single layer including the above-described material. In an embodiment, at least one of the source electrode SE and the drain electrode DE may have a multi-layer structure of Ti/Al/Ti.

The via insulating layer 110 may be disposed on the interlayer insulating layer 107. The via insulating layer 110 may be disposed on the source electrode SE and the drain electrode DE. The via insulating layer 110 is shown as a single layer, but is not limited thereto and may be formed as a multi-layer. The via insulating layer 110 may be an organic insulating layer including an organic material. The via insulating layer 110 may include an organic insulating material, such as a general-purpose polymer such as polymethylmethacrylate (PMMA) or polystyrene (PS), a polymer derivative having a phenol-based group, an acrylic polymer, an imide-based polymer, an aryl ether-based polymer, an amide-based polymer, a fluorine-based polymer, a p-xylene-based polymer, a vinyl alcohol-based polymer, and a blend thereof. The via insulating layer 110 may planarize upper surfaces of the first to third pixel circuits PC1, PC2, and PC3, thereby planarizing surfaces on which the first to third organic light-emitting diodes OLED1, OLED2, and OLED3 are disposed.

The first to third organic light-emitting diodes OLED1, OLED2, and OLED3 may be respectively electrically connected to the first to third pixel circuits PC1, PC2, and PC3 disposed between the substrate 100 and the first to third organic light-emitting diodes OLED1, OLED2, and OLED3 in a direction perpendicular to the upper surface of the substrate 100 (e.g., the z-direction).

Each of the first to third organic light-emitting diodes OLED1, OLED2, and OLED3 may have a stacked structure of a pixel electrode, an intermediate layer, and a counter electrode. The first organic light-emitting diode OLED1 may include a first pixel electrode 210a, a first intermediate layer 220a, and a counter electrode 230. The first pixel electrode 210a may be electrically connected to the first pixel circuit PC1. The second organic light-emitting diode OLED2 may include a second pixel electrode 210b, a second intermediate layer 220b, and the counter electrode 230. The second pixel electrode 210b may be electrically connected to the second pixel circuit PC2. The third organic light-emitting diode OLED3 may include a third pixel electrode 210c, a third intermediate layer 220c, and the counter electrode 230. The third pixel electrode 210c may be electrically connected to the third pixel circuit PC3.

The first to third pixel electrodes 210a, 210b, and 210c may be disposed on the via insulating layer 110. The first to third pixel electrodes 210a, 210b, and 210c may be respectively electrically connected to the thin-film transistors TFT respectively provided in the first to third pixel circuits PC1, PC2, and PC3. For example, the first pixel electrode 210a may be electrically connected to the thin-film transistor TFT of the first pixel circuit PC1 through a contact hole of the via insulating layer 110.

Each of the first to third pixel electrodes 210a, 210b, and 210c may be a transmissive electrode, a semi-transmissive electrode, or a reflective electrode. When each of the first to third pixel electrodes 210a, 210b, and 210c is a transmissive electrode, each of the first to third pixel electrodes 210a, 210b, and 210c may include a transparent conductive oxide, such as indium tin oxide (ITO), indium zinc oxide (ZnO), indium oxide (In₂O₃), indium gallium oxide (IGO), or aluminum zinc oxide (AZO). When each of the first to third pixel electrodes 210a, 210b, and 210c is a semi-transmissive electrode or a reflective electrode, each of the first to third pixel electrodes 210a, 210b, and 210c may include a reflective film including silver (Ag), magnesium (Mg), aluminum (Al), platinum (Pt), palladium (Pd), gold (Au), nickel (Ni), neodymium (Nd), iridium (Ir), chromium (Cr), Lithium (Li), calcium (Ca), or a compound thereof.

Each of the first to third pixel electrodes 210a, 210b, and 210c may have a single-layer structure including a single layer or a multi-layer structure including a plurality of layers. In an embodiment, each of the first to third pixel electrodes 210a, 210b, and 210c may be provided as a reflective electrode and may have a stacked structure of at least one reflective film and at least one transparent conductive layer. For example, each of the first to third pixel electrodes 210a, 210b, and 210c may have a triple-layer structure in which a transparent conductive layer including a transparent conductive oxide is disposed on and below the above-described reflective film. For example, each of the first to third pixel electrodes 210a, 210b, and 210c may have a stacked structure of ITO/Ag/ITO.

The pixel-defining layer 130 may be disposed on the via insulating layer 110. As shown in FIGS. 7A and 7B, the pixel-defining layer 130 may have the first pixel opening OP1 defining each of emission areas of the first to third organic light-emitting diodes OLED1, OLED2, and OLED3 disposed in the first display area DA1, and the second pixel opening OP2 defining each of emission areas of the first to third organic light-emitting diodes OLED1, OLED2, and OLED3 disposed in the second display area DA2.

In the first display area DA1, the pixel-defining layer 130 may be disposed on the first to third pixel electrodes 210a, 210b, and 210c and may include the first-1 pixel opening OP1a exposing a portion of the first pixel electrode 210a, the first-2 pixel opening OP1b exposing a portion of the second pixel electrode 210b, and the first-3 pixel opening OP1c exposing a portion of the third pixel electrode 210c. For example, the first-1 pixel opening OP1a may define an emission area EA1a of the first organic light-emitting diode OLED1 disposed in the first display area DA1. For example, the first-2 pixel opening OP1b may define an emission area EA1b of the second organic light-emitting diode OLED2 disposed in the first display area DA1. For example, the first-3 pixel opening OP1c may define an emission area EA1c of the third organic light-emitting diode OLED3 disposed in the first display area DA1.

In the second display area DA2, the pixel-defining layer 130 may be disposed on the first to third pixel electrodes 210a, 210b, and 210c and may include the second-1 pixel opening OP2a exposing a portion of the first pixel electrode 210a, the second-2 pixel opening OP2b exposing a portion of the second pixel electrode 210b, and the second-3 pixel opening OP2c exposing a portion of the third pixel electrode 210c. For example, the second-1 pixel opening OP2a may define an emission area EA2a of the first organic light-emitting diode OLED1 disposed in the second display area DA2. For example, the second-2 pixel opening OP2b may define an emission area EA2b of the second organic light-emitting diode OLED2 disposed in the second display area DA2. For example, the second-3 pixel opening OP2c may define an emission area EA2c of the third organic light-emitting diode OLED3 disposed in the second display area DA2.

In the first display area DA1, at least portions of upper surfaces of the first to third pixel electrodes 210a, 210b, and 210c may be exposed by the first-1 pixel opening OP1a, the first-2 pixel opening OP1b, and the first-3 pixel opening OP1c. In the second display area DA2, at least portions of upper surfaces of the first to third pixel electrodes 210a, 210b, and 210c may be exposed by the second-1 pixel opening OP2a, the second-2 pixel opening OP2b, and the second-3 pixel opening OP2c.

The pixel-defining layer 130 may increase a distance between an edge of each of the first to third pixel electrodes 210a, 210b, and 210c and the counter electrode 230, thereby preventing arcs or the like from occurring at the edge of each of the first to third pixel electrodes 210a, 210b, and 210c. The pixel-defining layer 130 may include, for example, an organic material, such as polyimide or hexamethyldisiloxane (HMDSO).

The first to third intermediate layers 220a, 220b, and 220c may be respectively disposed on the first to third pixel electrodes 210a, 210b, and 210c. The first intermediate layer 220a may be disposed between the first pixel electrode 210a and the counter electrode 230. The second intermediate layer 220b may be disposed between the second pixel electrode 210b and the counter electrode 230. The third intermediate layer 220c may be disposed between the third pixel electrode 210c and the counter electrode 230. Each of the first to third intermediate layers 220a, 220b, and 220c may be disposed in a pixel opening of the pixel-defining layer 130.

The first intermediate layer 220a may include a first emission layer emitting light of a first color, the second intermediate layer 220b may include a second emission layer emitting light of a second color, and the third intermediate layer 220c may include a third emission layer emitting light of a third color. In an embodiment, the first to third emission layers may emit light of different wavelengths. For example, the first emission layer may emit light of a red wavelength, the second emission layer may emit light of a green wavelength, and the third emission layer may emit light of a blue wavelength. The first to third emission layers may be patterned and provided for each pixel.

A first functional layer may be disposed below the first to third emission layers, and a second functional layer may be further disposed above the first to third emission layers. The first functional layer and the second functional layer may be formed as a single body across a plurality of pixels above the substrate 100. For example, the first functional layer may include a hole transport layer (HTL) or may include an HTL and a hole injection layer (HIL). The second functional layer may include an electron transport layer (ETL) and/or an electron injection layer (EIL). In an embodiment, the second functional layer may be omitted.

The counter electrode 230 may be disposed on the first to third pixel electrodes 210a, 210b, and 210c to face each of the first to third pixel electrodes 210a, 210b, and 210c. The counter electrode 230 may be disposed on the first to third intermediate layers 220a, 220b, and 220c. Unlike the first to third pixel electrodes 210a, 210b, and 210c, which are patterned apart from each other, the counter electrode 230 may be provided as a single body above the substrate 100. That is, the counter electrode 230 may be disposed across a plurality of subpixels disposed in the display area DA (see FIG. 1).

The counter electrode 230 may include a conductive material having a low work function. The counter electrode 230 may include, for example, silver (Ag), magnesium (Mg), aluminum (AI), platinum (Pt), palladium (Pd), gold (Au), nickel (Ni), neodymium (Nd), iridium (Ir), chromium (Cr), lithium (Li), calcium (Ca), lithium fluoride (LiF), or an alloy thereof. The counter electrode 230 may be formed as a single layer or multi-layer.

In some embodiments, a capping layer (not shown) may be further disposed on the counter electrode 230. The capping layer may include LiF, an inorganic material, or/and an organic material.

The encapsulation member 300 may be disposed on the first to third organic light-emitting diodes OLED1, OLED2, and OLED3 to seal the first to third organic light-emitting diodes OLED1, OLED2, and OLED3. The encapsulation member 300 may be disposed on the counter electrode 230. The encapsulation member 300 may include at least one inorganic encapsulation layer and at least one organic encapsulation layer. In an embodiment, the encapsulation member 300 may include a first inorganic encapsulation layer 310, an organic encapsulation layer 320, and a second inorganic encapsulation layer 330 that are sequentially stacked.

Each of the first and second inorganic encapsulation layers 310 and 330 may include at least one inorganic insulating material. The inorganic insulating material may include aluminum oxide, tantalum oxide, hafnium oxide, zinc oxide, silicon oxide, silicon nitride, or/and silicon oxynitride.

The organic encapsulation layer 320 may include a polymer-based material. The polymer-based material may include acrylic resin, epoxy-based resin, polyimide, polyethylene, and the like. The acrylic resin may include, for example, polymethyl methacrylate, polyacrylic acid, and the like.

The input sensing layer 400 may be disposed on the encapsulation member 300. The input sensing layer 400 may include a lower insulating layer 410, the touch insulating layer 430, a first touch conductive pattern 420, and a second touch conductive pattern 440. The input sensing layer 400 may obtain coordinate information according to an external input, for example, a touch event of an object such as a finger or a stylus pen. The input sensing layer 400 may detect an external input by a mutual capacitance method or a self-capacitance method.

The lower insulating layer 410 may be disposed on the encapsulation member 300. The touch insulating layer 430 may be disposed on the lower insulating layer 410. Each of the lower insulating layer 410 and the touch insulating layer 430 may include an insulating material. In an embodiment, each of the lower insulating layer 410 and the touch insulating layer 430 may include at least one of an inorganic material and an organic material.

The first touch conductive pattern 420 may be disposed on the lower insulating layer 410. The first touch conductive pattern 420 may be disposed between the lower insulating layer 410 and the touch insulating layer 430. The touch insulating layer 430 may cover the first touch conductive pattern 420.

As shown in FIG. 7A, in the first display area DA1, the touch insulating layer 430 may include the first protrusions 430P1 that respectively overlap the emission areas of the first to third organic light-emitting diodes OLED1, OLED2, and OLED3. For example, in the first display area DA1, the touch insulating layer 430 may include the first-1 protrusion 430P1a overlapping the emission area EA1a of the first organic light-emitting diode OLED1, the first-2 protrusion 430P1b overlapping the emission area EA1b of the second organic light-emitting diode OLED2, and the first-3 protrusion 430P1c overlapping the emission area EA1c of the third organic light-emitting diode OLED3 in a plan view.

As shown in FIG. 7B, in the second display area DA2, the touch insulating layer 430 may include the second protrusions 430P2 that respectively overlap the emission areas of the first to third organic light-emitting diodes OLED1, OLED2, and OLED3. For example, in the second display area DA2, the touch insulating layer 430 may include the second-1 protrusion 430P2a overlapping the emission area EA2a of the first organic light-emitting diode OLED1, the second-2 protrusion 430P2b overlapping the emission area EA2b of the second organic light-emitting diode OLED2, and the second-3 protrusion 430P2c overlapping the emission area EA2c of the third organic light-emitting diode OLED3 in a plan view.

The touch insulating layer 430 may define the recess 430R therein by the first protrusions 430P1 and the second protrusions 430P2. The recess 430R of the touch insulating layer 430 may be defined as a portion having a relatively low upper surface with respect to upper surfaces of the first and second protrusions 430P1 and 430P2.

As shown in FIGS. 7A and 7B, the touch insulating layer 430 may be formed as a single layer. For example, the touch insulating layer 430 may have a stepped structure having the first and second protrusions 430P1 and 430P2 and the recess 430R through a halftone mask process. In another embodiment, the touch insulating layer 430 may include a plurality of layers.

The second touch conductive pattern 440 may be disposed on the touch insulating layer 430. The second touch conductive pattern 440 may be disposed on the recess 430R of the touch insulating layer 430. A portion of the second touch conductive pattern 440 may be disposed between adjacent protrusions of the touch insulating layer 430. For example, a portion of the second touch conductive pattern 440 may be disposed between the first-1 protrusion 430P1a and the first-2 protrusion 430P1b of the touch insulating layer 430.

For example, each of the first touch conductive pattern 420 and the second touch conductive pattern 440 may have a single-layer structure or a stacked multi-layer structure. A conductive layer having a single-layer structure may include a metal layer or a transparent conductive layer. The metal layer may include, for example, molybdenum (Mo), silver (Ag), titanium (Ti), copper (Cu), aluminum (AI), and an alloy thereof. The transparent conductive layer may include, for example, a transparent conductive oxide, such as indium tin oxide (ITO), indium zinc oxide (IZO), zinc oxide (ZnO), or indium tin zinc oxide (ITZO). Also, the transparent conductive layer may include a conductive polymer, metal nanowires, graphene, and the like.

A conductive layer having a multi-layer structure may include multiple metal layers. The multiple metal layers may have, for example, a three-layer structure of Ti/Al/Ti. The conductive layer having a multi-layer structure may include at least one metal layer and at least one transparent conductive layer.

The first touch conductive pattern 420 and the second touch conductive pattern 440 may be electrically connected to each other through a contact hole. In an embodiment, each of the first touch conductive pattern 420 and the second touch conductive pattern 440 may have a mesh structure to allow light emitted from the first to third organic light-emitting diodes OLED1, OLED2, and OLED3 to pass therethrough. In this case, each of the first touch conductive pattern 420 and the second touch conductive pattern 440 may be disposed not to overlap the emission areas of the first to third organic light-emitting diodes OLED1, OLED2, and OLED3 in a plan view.

The first light-blocking layer 510 may be disposed on the input sensing layer 400. The first light-blocking layer 510 may be disposed on the recess 430R of the touch insulating layer 430. The first light-blocking layer 510 may cover the second touch conductive pattern 440. The first light-blocking layer 510 may be disposed in a groove defined by side surfaces of the protrusions 430P of the touch insulating layer 430 and an upper surface of the recess 430R of the touch insulating layer 430. The first light-blocking layer 510 may not overlap the first protrusions 430P1 and the second protrusions 430P2 of the touch insulating layer 430. The first light-blocking layer 510 may not overlap the emission areas of the first to third organic light-emitting diodes OLED1, OLED2, and OLED3. In a cross-sectional view, the first light-blocking layer 510 may be disposed between the protrusions 430P of the touch insulating layer 430 that are adjacent to each other. For example, the first light-blocking layer 510 may be disposed between the first-1 protrusion 430P1a and the first-2 protrusion 430P1b and between the first-2 protrusion 430P1b and the first-3 protrusion 430P1c. For example, the first light-blocking layer 510 may be disposed between the second-1 protrusion 430P2a and the second-2 protrusion 430P2b and between the second-2 protrusion 430P2b and the second-3 protrusion 430P2c.

As in a plan view, in a cross-sectional view, the minimum distance D1a between the first-1 protrusion 430P1a and the first light-blocking layer 510 may be substantially the same as the minimum distance D1b between the second-1 protrusion 430P2a and the first light-blocking layer 510. In a cross-sectional view, the minimum distance D2a between the first-2 protrusion 430P1b and the first light-blocking layer 510 may be substantially the same as the minimum distance D2b between the second-2 protrusion 430P2b and the first light-blocking layer 510. In a cross-sectional view, the minimum distance D3a between the first-3 protrusion 430P1c and the first light-blocking layer 510 may be substantially the same as the minimum distance D3b between the second-3 protrusion 430P2c and the first light-blocking layer 510.

The first light-blocking layer 510 may at least partially absorb external light or internal reflected light. For example, the first light-blocking layer 510 may include a black pigment. For example, the first light-blocking layer 510 may be a black matrix.

As shown in FIG. 7A, the first light-blocking layer 510 may have the first opening 510OP1 overlapping each of the emission areas of the first to third organic light-emitting diodes OLED1, OLED2, and OLED3 disposed in the first display area DA1. For example, in the first display area DA1, the first light-blocking layer 510 may include the first-1 opening 510OP1a overlapping the emission area EA1a of the first organic light-emitting diode OLED1, the first-2 opening 510OP1b overlapping the emission area EA1b of the second organic light-emitting diode OLED2, and the first-3 opening 510OP1c overlapping the emission area EA1c of the third organic light-emitting diode OLED3 in a plan view.

As shown in FIG. 7B, the first light-blocking layer 510 may have the second opening 510OP2 overlapping each of the emission areas of the first to third organic light-emitting diodes OLED1, OLED2, and OLED3 disposed in the second display area DA2. For example, in the second display area DA2, the first light-blocking layer 510 may include the second-1 opening 510OP2a overlapping the emission area EA2a of the first organic light-emitting diode OLED1, the second-2 opening 510OP2b overlapping the emission area EA2b of the second organic light-emitting diode OLED2, and the second-3 opening 510OP2c overlapping the emission area EA2c of the third organic light-emitting diode OLED3 in a plan view.

The anti-reflection layer 600 may be disposed on the input sensing layer 400. The anti-reflection layer 600 may include a color filter layer 610 and an overcoat layer 620.

The color filter layer 610 may be disposed on the touch insulating layer 430 and the second touch conductive pattern 440. In the first display area DA1, the color filter layer 610 may include a first-1 color filter 611a, a first-2 color filter 612a, and a first-3 color filter 613a. In the second display area DA2, the color filter layer 610 may include a second-1 color filter 611b, a second-2 color filter 612b, and a second-3 color filter 613b.

The first-1 color filter 611a, the first-2 color filter 612a, and the first-3 color filter 613a may respectively overlap the emission area EA1a of the first organic light-emitting diode OLED1, the emission area EA1b of the second organic light-emitting diode OLED2, and the emission area EA1c of the third organic light-emitting diode OLED3, which are disposed in the first display area DA1. The first-1 color filter 611a, the first-2 color filter 612a, and the first-3 color filter 613a may respectively selectively transmit emitted light emitted from the emission area EA1a of the first organic light-emitting diode OLED1, the emission area EA1b of the second organic light-emitting diode OLED2, and the emission area EA1c of the third organic light-emitting diode OLED3, which are disposed in the first display area DA1. For example, the first-1 color filter 611a may be a red color filter transmitting red light, the first-2 color filter 612a may be a green color filter transmitting green light, and the first-3 color filter 613a may be a blue color filter transmitting blue light.

A portion of the first-1 color filter 611a may be disposed in the first-1 opening 510OP1a of the first light-blocking layer 510. For example, a portion of the first-1 color filter 611a may be disposed between the first light-blocking layer 510 and the first-1 protrusion 430P1a. A portion of the first-2 color filter 612a may be disposed in the first-2 opening 510OP1b of the first light-blocking layer 510. For example, a portion of the first-2 color filter 612a may be disposed between the first light-blocking layer 510 and the first-2 protrusion 430P1b. A portion of the first-3 color filter 613a may be disposed in the first-3 opening 510OP1c of the first light-blocking layer 510. For example, a portion of the first-3 color filter 613a may be disposed between the first light-blocking layer 510 and the first-3 protrusion 430P1c. A portion of the second-1 color filter 611b may be disposed in the second-1 opening 510OP2a of the first light-blocking layer 510. For example, a portion of the second-1 color filter 611b may be disposed between the first light-blocking layer 510 and the second-1 protrusion 430P2a. A portion of the second-2 color filter 612b may be disposed in the second-2 opening 510OP2b of the first light-blocking layer 510. For example, a portion of the second-2 color filter 612b may be disposed between the first light-blocking layer 510 and the second-2 protrusion 430P2b. A portion of the second-3 color filter 613b may be disposed in the second-3 opening 510OP2c of the first light-blocking layer 510. For example, a portion of the second-3 color filter 613b may be disposed between the first light-blocking layer 510 and the second-3 protrusion 430P2c.

Color filters disposed adjacent to each other may overlap each other in an area overlapping the first light-blocking layer 510. For example, in the first display area DA1, the first-1 color filter 611a and the first-2 color filter 612a may overlap each other in an area overlapping the first light-blocking layer 510. For example, in the first display area DA1, the first-2 color filter 612a and the first-3 color filter 613a may overlap each other in an area overlapping the first light-blocking layer 510. For example, in the second display area DA2, the second-1 color filter 611b and the second-2 color filter 612b may overlap each other in an area overlapping the first light-blocking layer 510. For example, in the second display area DA2, the second-2 color filter 612b and the second-3 color filter 613b may overlap each other in an area overlapping the first light-blocking layer 510 in a plan view.

The second-1 color filter 611b, the second-2 color filter 612b, and the second-3 color filter 613b may respectively overlap the emission area EA2a of the first organic light-emitting diode OLED1, the emission area EA2b of the second organic light-emitting diode OLED2, and the emission area EA2c of the third organic light-emitting diode OLED3, which are disposed in the second display area DA2. The second-1 color filter 611b, the second-2 color filter 612b, and the second-3 color filter 613b may respectively selectively transmit emitted light emitted from the emission area EA2a of the first organic light-emitting diode OLED1, the emission area EA2b of the second organic light-emitting diode OLED2, and the emission area EA2c of the third organic light-emitting diode OLED3, which are disposed in the second display area DA2. For example, the second-1 color filter 611b may be a red color filter transmitting red light, the second-2 color filter 612b may be a green color filter transmitting green light, and the second-3 color filter 613b may be a blue color filter transmitting blue light.

The color filter layer 610 may include a polymer photosensitive resin and a pigment or dye. The first-1 color filter 611a may include a pigment or dye corresponding to light emitted from the first organic light-emitting diode OLED1. The first-2 color filter 612a may include a pigment or dye corresponding to light emitted from the second organic light-emitting diode OLED2. The first-3 color filter 613a may include a pigment or dye corresponding to light emitted from the third organic light-emitting diode OLED3. The second-1 color filter 611b may include a pigment or dye corresponding to light emitted from the first organic light-emitting diode OLED1. The second-2 color filter 612b may include a pigment or dye corresponding to light emitted from the second organic light-emitting diode OLED2. The second-3 color filter 613b may include a pigment or dye corresponding to light emitted from the third organic light-emitting diode OLED3.

In a display device according to a comparative example, the first light-blocking layer 510 is formed on the touch insulating layer 430 that does not have the recess 430R, and the first opening 510OP1 of the first light-blocking layer 510 in the first display area DA1 and the second opening 510OP2 of the first light-blocking layer 510 in the second display area DA2 have different sizes (areas), and thus, corresponding color filters in the first display area DA1 and the second display area DA2 are formed to have different thicknesses. In detail, because the size (area) of the first opening 510OP1 of the first light-blocking layer 510 is less than the size (area) of the corresponding second opening 510OP2 of the first light-blocking layer 510, the thickness of a color filter in the first display area DA1 is greater than the thickness of a corresponding color filter in the second display area DA2. As such, when corresponding color filters in the first display area DA1 and the second display area DA2 are formed to have different thicknesses, the first display area DA1 and the second display area DA2 may have different luminescence efficiencies, and thus, afterimages in the form of stains may occur. Alternatively, the organic light-emitting diodes disposed in the first display area DA1 and the organic light-emitting diodes disposed in the second display area DA2 may have different element lifespans.

In the display device 1 according to an embodiment, as the touch insulating layer 430 defines the recess 430R therein, the first light-blocking layer 510 may be formed on the recess 430R of the touch insulating layer 430, and thus, corresponding color filters of the color filter layer 610 in the first display area DA1 and the second display area DA2 may have substantially the same thickness. Because the minimum distance (e.g., D1a) between the first light-blocking layer 510 and the first protrusion 430P1 disposed in the first display area DA1 is substantially the same as the minimum distance (e.g., D1b) between the first light-blocking layer 510 and the second protrusion 430P2 disposed corresponding to the first protrusion 430P1 in the second display area DA2, corresponding color filters of the color filter layer 610 in the first display area DA1 and the second display area DA2 may have substantially the same thickness. For example, a thickness TH1a of the first-1 color filter 611a may be substantially the same as a thickness TH1b of the second-1 color filter 611b. For example, a thickness TH2a of the first-2 color filter 612a may be substantially the same as a thickness TH2b of the second-2 color filter 612b. For example, a thickness TH3a of the first-3 color filter 613a may be substantially the same as a thickness TH3b of the second-3 color filter 613b.

As such, because corresponding color filters in the first display area DA1 and the second display area DA2 are formed to have substantially the same thickness, the occurrence of afterimages in the form of stains in the first display area DA1 and the second display area DA2 may be prevented or reduced, and thus, the display quality of the display device 1 may be improved. Also, the occurrence of a difference in element lifespan between the organic light-emitting diodes disposed in the first display area DA1 and the organic light-emitting diodes disposed in the second display area DA2 may be prevented or reduced.

The overcoat layer 620 may be a light-transmissive layer that does not have a color in the visible light band and may cover irregularities created during the formation of the color filter layer 610 and the first light-blocking layer 510 and provide a flat upper surface.

The optical functional layer 700 may be disposed on the anti-reflection layer 600. The optical functional layer 700 may include a second light-blocking layer 710 disposed in the first display area DA1, and a planarization layer 720 disposed in the first display area DA1 and the second display area DA2 to planarize an upper surface of the second light-blocking layer 710.

The second light-blocking layer 710 may be disposed in the first display area DA1 and may not be disposed in the second display area DA2. For example, the second light-blocking layer 710 may define an opening overlapping the emission area EA1a of the first organic light-emitting diode OLED1 disposed in the first display area DA1 in a plan view, and the opening of the second light-blocking layer 710 may overlap the first-1 opening 510OP1a of the first light-blocking layer 510 in a plan view. For example, the second light-blocking layer 710 may define an opening overlapping the emission area EA1b of the second organic light-emitting diode OLED2 disposed in the first display area DA1, and the opening of the second light-blocking layer 710 may overlap the first-2 opening 510OP1b of the first light-blocking layer 510 in a plan view. For example, the second light-blocking layer 710 may define an opening overlapping the emission area EA1c of the third organic light-emitting diode OLED3 disposed in the first display area DA1, and the opening of the second light-blocking layer 710 may overlap the first-3 opening 510OP1c of the first light-blocking layer 510 in a plan view.

The second light-blocking layer 710 may overlap the recess 430R of the touch insulating layer 430. The second light-blocking layer 710 may overlap the first light-blocking layer 510. The second light-blocking layer 710 may not overlap the first protrusion 430P1 of the touch insulating layer 430 in a plan view.

The second light-blocking layer 710 may at least partially absorb external light or internal reflected light. For example, the second light-blocking layer 710 may include a black pigment. For example, the second light-blocking layer 710 may be a black matrix.

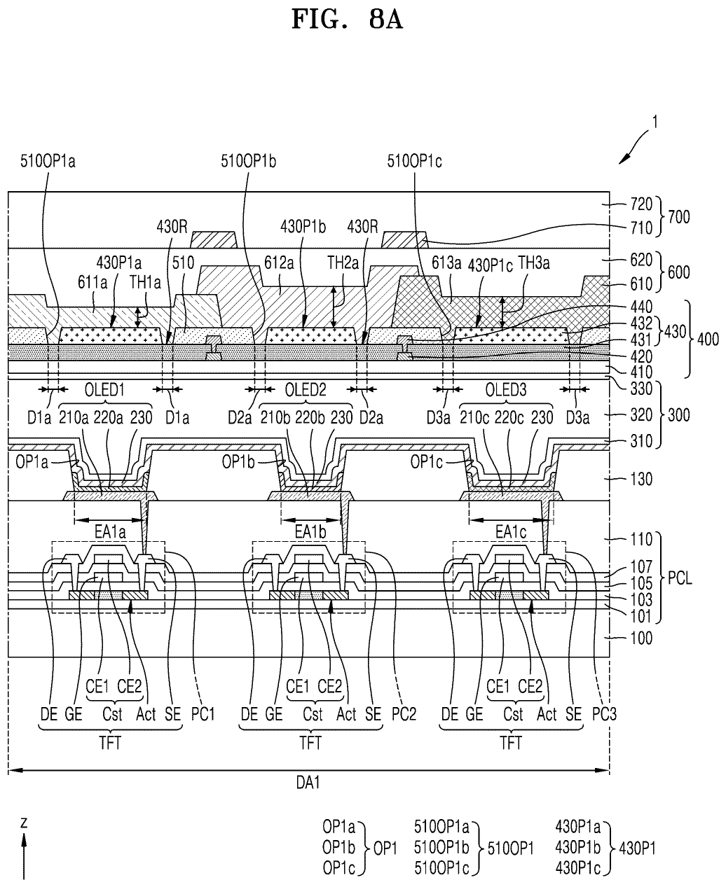

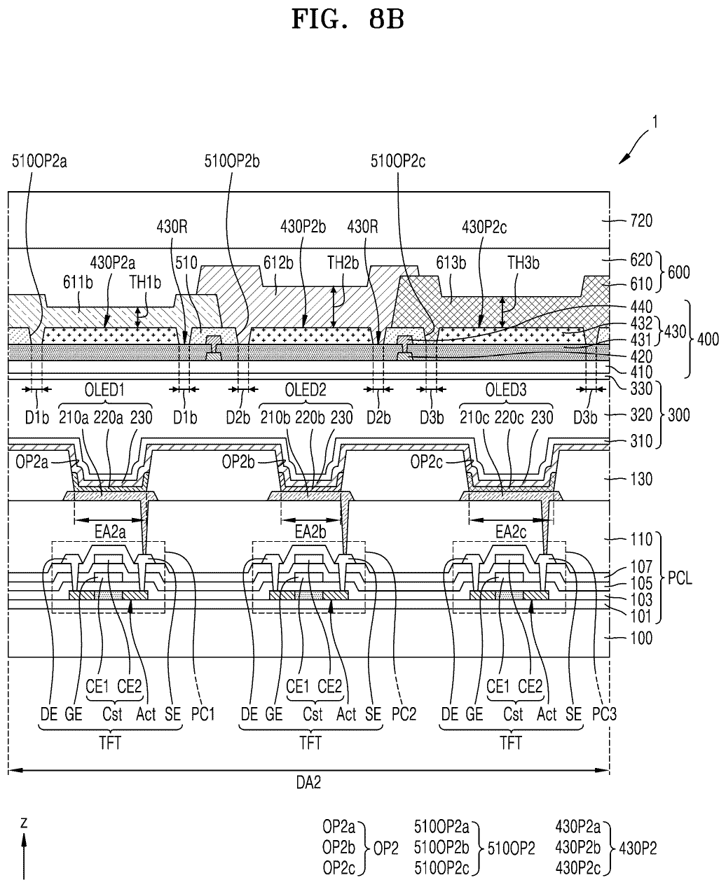

FIGS. 8A and 8B are respectively schematic cross-sectional views of the first display area DA1 and the second display area DA2 of the display device 1 according to an embodiment. FIGS. 8A and 8B show modified examples of the embodiments described with reference to FIGS. 7A and 7B. Thus, redundant descriptions thereof will be omitted or simplified, and the modified parts will be mainly described.

Referring to FIGS. 8A and 8B, the touch insulating layer 430 may include a plurality of layers including a first layer 431 and a second layer 432 on the first layer 431. For example, the first layer 431 of the touch insulating layer 430 may have a flat upper surface, and the second layer 432 of the touch insulating layer 430 may include a plurality of protruding patterns disposed on the first layer 431 to define the first protrusions 430P1 and the second protrusions 430P2.

As shown in FIG. 8A, the second layer 432 of the touch insulating layer 430 may be disposed in the first opening 510OP1 of the first light-blocking layer 510. As shown in FIG. 8B, the second layer 432 of the touch insulating layer 430 may be disposed in the second opening 510OP2 of the first light-blocking layer 510. For example, the protruding patterns of the second layer 432 of the touch insulating layer 430 may be disposed in the first-1 opening 510OP1a, the first-2 opening 510OP1b, the first-3 opening 510OP1c, the second-1 opening 510OP2a, the second-2 opening 510OP2b, and the second-3 opening 510OP2c of the first light-blocking layer 510.

In forming the touch insulating layer 430, after forming the first layer 431 having a flat upper surface, the second layer 432 may be stacked on the first layer 431, and the second layer 432 may be patterned to form protruding patterns.

Each of the first layer 431 and the second layer 432 of the touch insulating layer 430 may include at least one of an inorganic material and an organic material. The first layer 431 and the second layer 432 of the touch insulating layer 430 may include different materials. For example, the first layer 431 of the touch insulating layer 430 may include an organic material, and the second layer 432 of the touch insulating layer 430 may include an inorganic material.

The display device according to the embodiment may be applied to various electronic devices. An electronic device according to an embodiment of the present disclosure may include the display device (e.g., the display device of FIG. 1) described above, and may further include modules or devices having additional functions in addition to the display device.

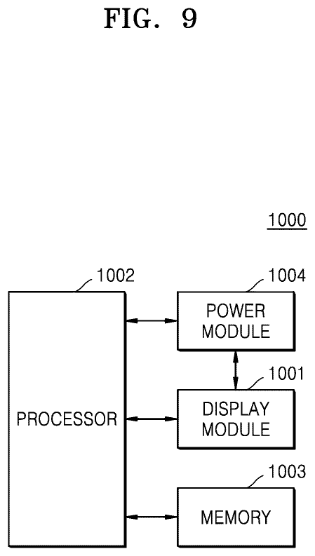

FIG. 9 is a block diagram of an electronic device according to an embodiment.

Referring to FIG. 9, an electronic device 1000 according to an embodiment may include a display module 1001, a processor 1002, a memory 1003, and a power module 1004.

The processor 1002 may include at least one of a central processing unit (CPU), an application processor (AP), a graphic processing unit (GPU), a communication processor (CP), an image signal processor (ISP), and a controller.

The memory 1003 may store data information necessary for the operation of the processor 1002 or the display module 1001. When the processor 1002 executes an application stored in the memory 1003, an image data signal and/or an input control signal may be transmitted to the display module 1001, and the display module 1001 may process a signal received and output image information through a display screen.

The power module 1004 may include a power supply module such as a power adapter or a battery device, and a power conversion module that converts the power supplied by the power supply module to generate power necessary for the operation of the electronic device 1000.

At least one of the components of the electronic device 1000 described above may be included in the display device according to the embodiments described above. In addition, a part among the individual modules functionally included in one module may be included in the display device, and another part may be provided separately from the display device. For example, the display device may include the display module 1001, and the processor 1002, the memory 1003, and the power module 1004 may be provided in the form of other devices within the electronic device 1000 except for the display device.

In an embodiment, the display module 1001 included in the display device may drive based on the image data signal and the input control signal received from the processor 1002.

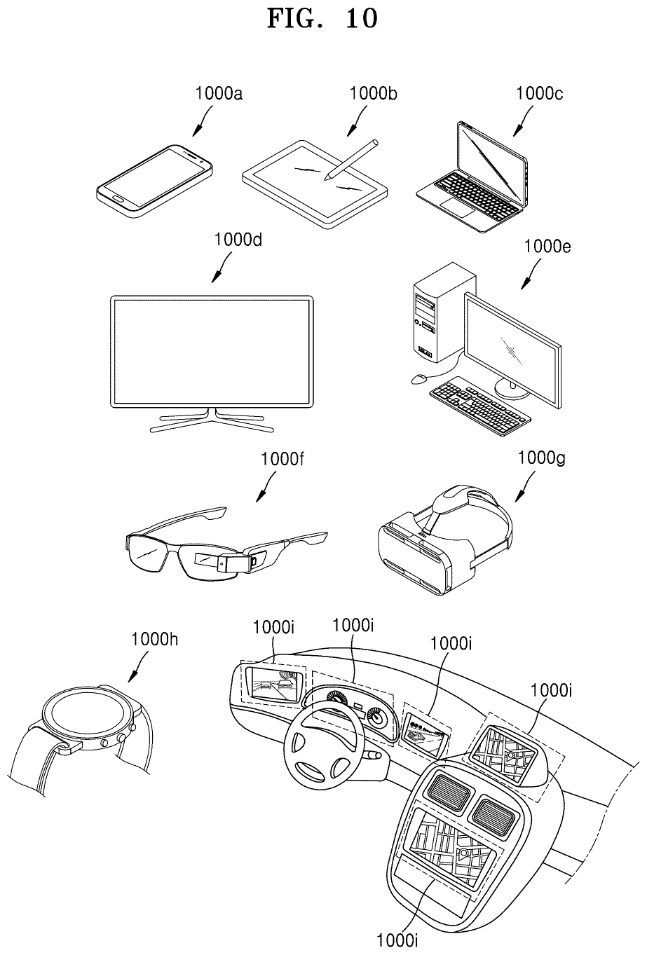

FIG. 10 is schematic diagrams of electronic devices according to various embodiments.

Referring to FIG. 10, various electronic devices to which display devices according to embodiments are applied may include not only image display electronic devices such as a smart phone 1000a, a tablet PC 1000b, a laptop 1000c, a TV 1000d, and a desk monitor 1000e, but also a wearable electronic device including display modules such as smart glasses 1000f, a head mounted display 1000g, and a smart watch 1000h, and a vehicle electronic device 1000i including a dashboard, a center fascia, and display modules such as a CID (Center Information Display) and a room mirror display disposed in the dashboard.

In a display device according to an embodiment, as a touch insulating layer has protrusions and a recess defined by the protrusions, color filter layers overlapping light-emitting elements that emit light of the same wavelength in each of a first display area and a second display area, respectively, may have substantially the same thickness. Accordingly, in the display device according to an embodiment, a difference in luminescence efficiency between the light-emitting elements in the first display area and the light-emitting elements in the second display area may be effectively reduced, and thus, the display quality of the display device may be improved.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display device comprising:
a substrate comprising a first display area and a second display area adjacent to the first display area;
a first display element disposed in the first display area;
a second display element disposed in the second display area and configured to emit light of a same wavelength as the first display element;
a first touch conductive pattern disposed on the first display element and the second display element;
a touch insulating layer covering the first touch conductive pattern, comprising protrusions, and providing a recess defined by the protrusions, the protrusions overlapping a first emission area of the first display element and a second emission area of the second display element, respectively, in a plan view;
a first light-blocking layer disposed on the recess of the touch insulating layer and defining a first opening and a second opening therein, the first opening overlapping the first emission area of the first display element, and the second opening overlapping the second emission area of the second display element in the plan view; and
a color filter layer disposed on the touch insulating layer and the first light-blocking layer and comprising a first color filter and a second color filter, the first color filter overlapping the first emission area of the first display element, and the second color filter overlapping the second emission area of the second display element in the plan view,
wherein an area of the first opening of the first light-blocking layer is less than an area of the second opening of the first light-blocking layer in the plan view.

2. The display device of claim 1, wherein a thickness of the first color filter is substantially the same as a thickness of a corresponding portion of the second color filter.

3. The display device of claim 1, wherein a portion of the first color filter is disposed between the first light-blocking layer and a protrusion overlapping the first emission area, from among the protrusions of the touch insulating layer, and
a portion of the second color filter is disposed between the first light-blocking layer and a protrusion overlapping the second emission area, from among the protrusions of the touch insulating layer in the plan view.

4. The display device of claim 1, wherein, in the plan view, a minimum distance between the first light-blocking layer and a protrusion overlapping the first emission area, from among the protrusions of the touch insulating layer, is substantially the same as a minimum distance between the first light-blocking layer and a protrusion overlapping the second emission area, from among the protrusions of the touch insulating layer.

5. The display device of claim 1, wherein the protrusions of the touch insulating layer do not overlap the first light-blocking layer in the plan view.

6. The display device of claim 1, further comprising a second touch conductive pattern disposed on the recess of the touch insulating layer,
wherein the first light-blocking layer covers the second touch conductive pattern.

7. The display device of claim 6, wherein the first touch conductive pattern and the second touch conductive pattern do not overlap the first emission area and the second emission area in the plan view.

8. The display device of claim 1, further comprising a second light-blocking layer disposed on the color filter layer and disposed in the first display area,
wherein the second light-blocking layer defines an opening overlapping the first opening of the first light-blocking layer in the plan view.

9. The display device of claim 1, further comprising a pixel-defining layer disposed on the substrate and defining a first pixel opening and a second pixel opening therein, the first pixel opening defining the first emission area, and the second pixel opening defining the second emission area,
wherein the first pixel opening overlaps the first opening of the first light-blocking layer in the plan view, and
the second pixel opening overlaps the second opening of the first light-blocking layer in the plan view.

10. The display device of claim 9, wherein, in the plan view, a minimum distance between the first pixel opening and the first light-blocking layer is less than a minimum distance between the second pixel opening and the second opening of the first light-blocking layer.

11. The display device of claim 1, wherein the touch insulating layer comprises a first layer and a second layer, the first layer having a flat upper surface, and the second layer being disposed on the first layer and arranged in the first opening and the second opening of the first light-blocking layer in the plan view, and
the second layer of the touch insulating layer defines the protrusions.

12. A display device comprising:
a substrate comprising a first display area and a second display area adjacent to the first display area;
a first display element disposed in the first display area;
a second display element disposed in the second display area and configured to emit light of a same wavelength as the first display element;
a touch conductive pattern disposed on the first display element and the second display element;
a touch insulating layer covering the touch conductive pattern and comprising a first protrusion and a second protrusion, the first protrusion overlapping a first emission area of the first display element, and the second protrusion overlapping a second emission area of the second display element in a plan view;
a first light-blocking layer disposed on the touch insulating layer and defining a first opening and a second opening therein, the first opening overlapping the first emission area of the first display element and having a greater area than the first protrusion, and the second opening overlapping the second emission area of the second display element and having a greater area than the second protrusion in the plan view; and
a color filter layer disposed on the touch insulating layer and the first light-blocking layer and comprising a first color filter and a second color filter, the first color filter overlapping the first emission area of the first display element, and the second color filter overlapping the second emission area of the second display element in the plan view,
wherein an area of the first opening of the first light-blocking layer is less than an area of the second opening of the first light-blocking layer in the plan view.

13. The display device of claim 12, wherein a thickness of the first color filter is substantially the same as a thickness of a corresponding portion of the second color filter.

14. The display device of claim 12, wherein a portion of the first color filter is disposed between the first protrusion and the first light-blocking layer, and
a portion of the second color filter is disposed between the second protrusion and the first light-blocking layer.

15. The display device of claim 12, wherein, in the plan view, a minimum distance between the first protrusion of the touch insulating layer and the first light-blocking layer is substantially the same as a minimum distance between the second protrusion of the touch insulating layer and the first light-blocking layer.

16. The display device of claim 12, wherein the first protrusion and the second protrusion of the touch insulating layer do not overlap the first light-blocking layer in the plan view.

17. The display device of claim 12, further comprising a second touch conductive pattern disposed on the touch insulating layer,
wherein the first light-blocking layer covers the second touch conductive pattern.

18. The display device of claim 12, further comprising a second light-blocking layer disposed on the color filter layer and disposed in the first display area,
wherein the second light-blocking layer defines an opening overlapping the first opening of the first light-blocking layer in the plan view.

19. The display device of claim 12, further comprising a pixel-defining layer disposed on the substrate and defining a first pixel opening and a second pixel opening therein, the first pixel opening defining the first emission area, and the second pixel opening defining the second emission area,
wherein the first pixel opening overlaps the first opening of the first light-blocking layer in the plan view, and
the second pixel opening overlaps the second opening of the first light-blocking layer in the plan view.

20. A display device comprising:
a substrate comprising a first display area and a second display area adjacent to the first display area;
a first display element group disposed in the first display area and comprising a plurality of light-emitting elements;
a second display element group disposed in the second display area and comprising a plurality of light-emitting elements;
an input sensing layer disposed on the first display element group and the second display element group; and
a first light-blocking layer disposed on the input sensing layer and defining first openings and second openings therein, the first openings overlapping emission areas of the plurality of light-emitting elements of the first display element group, respectively, and the second openings overlapping emission areas of the plurality of light-emitting elements of the second display element group, respectively, in a plan view,
wherein the input sensing layer comprises a first touch conductive pattern, a touch insulating layer on the first touch conductive pattern, and a second touch conductive pattern on the touch insulating layer,
the touch insulating layer comprises protrusions and provides a recess defined by the protrusions, the protrusions overlapping the emission areas of the plurality of light-emitting elements of the first display element group and the emission areas of the plurality of light-emitting elements of the second display element group, respectively, in the plan view,
the first light-blocking layer is disposed on the recess of the touch insulating layer,
the first display element group comprises a first-1 light-emitting element configured to emit light of a first wavelength,
the second display element group comprises a second-1 light-emitting element configured to emit light of a same wavelength as the first-1 light-emitting element, and
an area of a first opening overlapping an emission area of the first-1 light-emitting element, from among the first openings of the first light-blocking layer, is less than an area of a second opening overlapping an emission area of the second-1 light-emitting element, from among the second openings of the first light-blocking layer in the plan view.

21. The display device of claim 20, further comprising a color filter layer disposed on the input sensing layer and comprising a first-1 color filter and a second-1 color filter, the first-1 color filter overlapping the emission area of the first-1 light-emitting element, and the second-1 color filter overlapping the emission area of the second-1 light-emitting element in the plan view,
wherein a thickness of the first-1 color filter is substantially the same as a thickness of a corresponding portion of the second-1 color filter.

22. The display device of claim 21, wherein the first display element group further comprises a first-2 light-emitting element adjacent to the first-1 light-emitting element and configured to emit light of a second wavelength,
the second display element group further comprises a second-2 light-emitting element adjacent to the second-1 light-emitting element and configured to emit light of a same wavelength as the first-2 light-emitting element,
an area of a first opening overlapping an emission area of the first-2 light-emitting element, from among the first openings of the first light-blocking layer, is less than an area of a second opening overlapping an emission area of the second-2 light-emitting element, from among the second openings of the first light-blocking layer in the plan view,
the color filter layer further comprises a first-2 color filter and a second-2 color filter, the first-2 color filter overlapping the emission area of the first-2 light-emitting element, and the second-2 color filter overlapping the emission area of the second-2 light-emitting element in the plan view, and
a thickness of the first-2 color filter is substantially the same as a thickness of a corresponding portion of the second-2 color filter.

23. The display device of claim 22, wherein, in the plan view, the first-1 color filter and the first-2 color filter overlap each other in an area overlapping the first light-blocking layer, and
the second-1 color filter and the second-2 color filter overlap each other in an area overlapping the first light-blocking layer.

24. An electronic device comprising a display device,
wherein the display device comprises:
a substrate comprising a first display area and a second display area adjacent to the first display area;
a first display element disposed in the first display area;
a second display element disposed in the second display area and configured to emit light of a same wavelength as the first display element;
a first touch conductive pattern disposed on the first display element and the second display element;
a touch insulating layer covering the first touch conductive pattern, comprising protrusions, and providing a recess defined by the protrusions, the protrusions overlapping a first emission area of the first display element and a second emission area of the second display element, respectively, in a plan view;
a first light-blocking layer disposed on the recess of the touch insulating layer and defining a first opening and a second opening therein, the first opening overlapping the first emission area of the first display element, and the second opening overlapping the second emission area of the second display element in the plan view; and
a color filter layer disposed on the touch insulating layer and the first light-blocking layer and comprising a first color filter and a second color filter, the first color filter overlapping the first emission area of the first display element, and the second color filter overlapping the second emission area of the second display element in the plan view,
wherein an area of the first opening of the first light-blocking layer is less than an area of the second opening of the first light-blocking layer in the plan view.

25. The electronic device of claim 24, further comprising:
a display module;
a processor; a power module; and
a memory,
wherein the display device includes one of the display module, the processor, the power module, or the memory.
